(19) United States
(12) Patent Application Publication
(10) Pub. No.: US 2026/0005117 A1
(43) Pub. Date: Jan. 1, 2026

(54) SEMICONDUCTOR DIE PACKAGES INCLUDING NON-ACTIVE DIES AND METHODS OF FORMATION

(71) Applicant: Taiwan Semiconductor Manufacturing Company, Ltd., Hsinchu (TW)

(72) Inventors: Tzu Jung TIEN, Hsinchu County (TW); Jen-Yuan CHANG, Hsinchu City (TW)

(21) Appl. No.: 18/754,440

(22) Filed: Jun. 26, 2024

(51) Int. Cl. H01L 23/498; H01L 23/00; H01L 23/367; H01L 25/065

(52) U.S. Cl. CPC H01L 23/49838; H01L 23/3675; H01L 23/49816; H01L 24/05; H01L 24/13; H01L 25/0652; H01L 2224/05009; H01L 2224/05025; H01L 2224/13009; H01L 2224/13026; H01L 2924/01029; H01L 2924/1431; H01L 2924/1434; H01L 2924/15311; H01L 2924/351

(57) ABSTRACT

A first integrated circuit (IC) die is directly bonded together with a second IC die in a vertical arrangement in a semiconductor die package. The smaller physical size of the first IC die enables a plurality of non-active dies to be placed over the second IC die in areas not occupied by the first IC die. Including a plurality of non-active dies enables the non-active dies to be customized for the different attributes of different areas of the second IC die, including different thermal profiles of the different areas of the second IC die. In this way, including a plurality of non-active dies in the semiconductor die package may increase the thermal stability of the semiconductor die package, which may prolong the operational lifetime of the IC dies, may reduce the likelihood of failure of the IC dies, and/or may increase the overall reliability of the semiconductor die package.

### BACKGROUND

A semiconductor die package may include a plurality of integrated circuit (IC) dies that offer a variety of functionalities. Examples of IC dies include a system-on-chip (SoC) IC die, a dynamic random access memory (DRAM) IC die, a logic IC die, and/or a high bandwidth memory (HBM) IC die, among other examples. Some semiconductor die packages include an interposer that enables IC dies to be laterally arranged on the interposer. In, some semiconductor die packages IC dies are vertically arranged using three-dimensional (3D) packaging techniques such as direct bonding.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrams of an example of a semiconductor die package described herein.

FIGS. 2A-2I are diagrams of examples of top view layouts for non-active dies in a semiconductor die package described herein.

FIGS. 3A-3T are diagrams of an example implementation of forming a semiconductor die package described herein.

FIGS. 4A-4E are diagrams of an example of a semiconductor die package described herein.

FIGS. 5A-5E are diagrams of an example of a semiconductor die package described herein.

FIGS. 6A-6F are diagrams of examples of top view layouts for a semiconductor die package described herein.

FIG. 7 is a flowchart of an example process associated with forming a semiconductor die package described herein.

FIG. 8 is a flowchart of an example process associated with forming a semiconductor die package described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In a semiconductor die package, integrated circuit (IC) dies may have different attributes, such as different sizes, different materials (or different material compositions), different thermal requirements, and/or different structural requirements, among other examples. Additionally and/or alternatively, an IC die in a semiconductor die package may have regions of different functionality (e.g., a memory region, a power supply region, a logic region) that each have different attributes such as different sizes and/or different thermal requirements. The different attributes of different IC dies in a semiconductor die package, and/or the different attributes of different functional regions of an IC die in the semiconductor die package, may lead to layout challenges in the semiconductor die package. For example, different attributes of different functional regions of an IC die in the semiconductor die package may result in complex thermal management solutions and/or may result in having to account for different thermal expansion and contraction rates across the IC die, among other examples. If not addressed, these challenges may reduce the operational lifetime of the IC dies in the semiconductor die package and/or may lead to premature failure of the IC dies in the semiconductor die package, among other examples.

In implementations described herein, a physically smaller first IC die is directly bonded together with a physically lager second IC die in a vertical arrangement in a semiconductor die package. The smaller physical size of the first IC die enables a plurality of non-active dies to be placed over the second IC die in areas not occupied by the first IC die. Including a plurality of non-active dies enables the non-active dies to be customized for the different attributes of different areas of the second IC die. For example, different non-active dies may be manufactured to have different heat dissipation profiles for different areas of the second IC die that have different thermal requirements. As another example, different non-active dies may be manufactured to have different materials (or different material compositions) to account for areas of different rates of thermal expansion and contraction in the second IC die. In this way, including a plurality of non-active dies in the semiconductor die package may increase the thermal stability of the semiconductor die package, which may enable increased operational lifetime to be achieved for the IC dies, may reduce the likelihood of failure of the IC dies, and/or may increase the overall reliability of the semiconductor die package, among other examples.

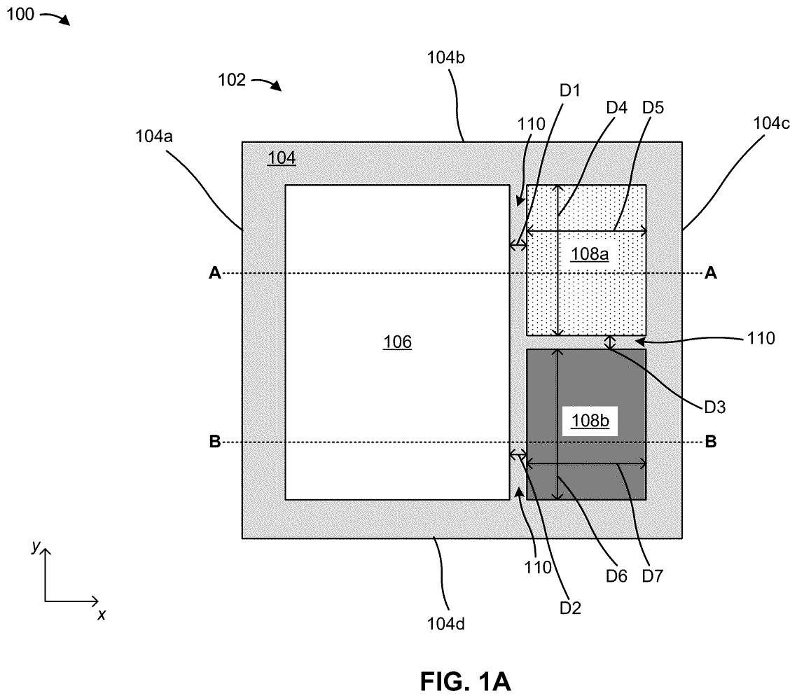

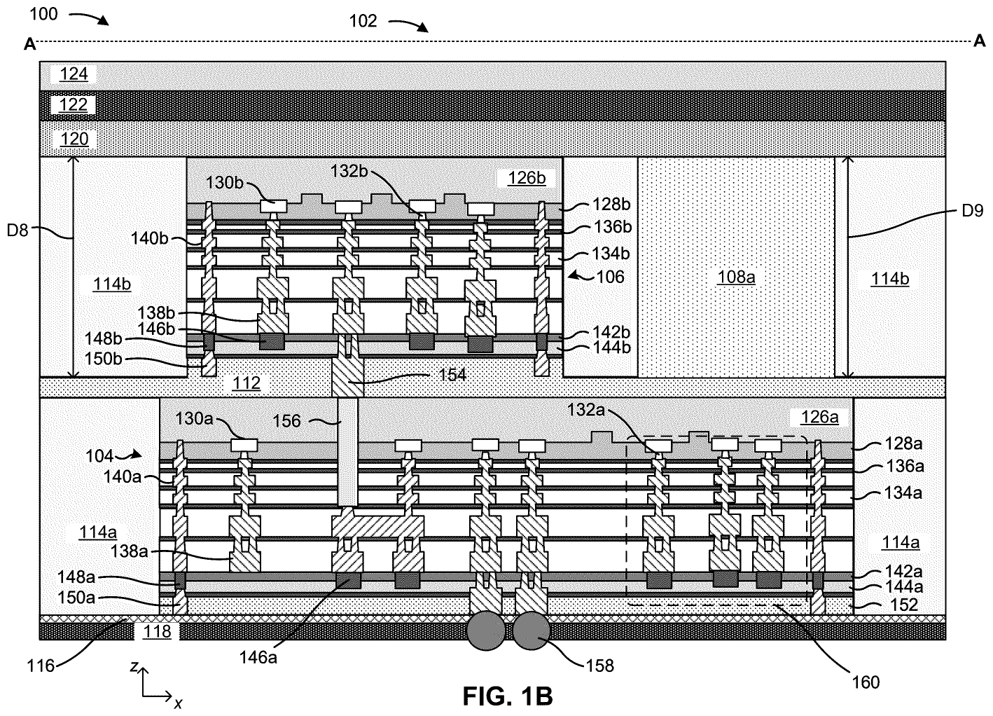

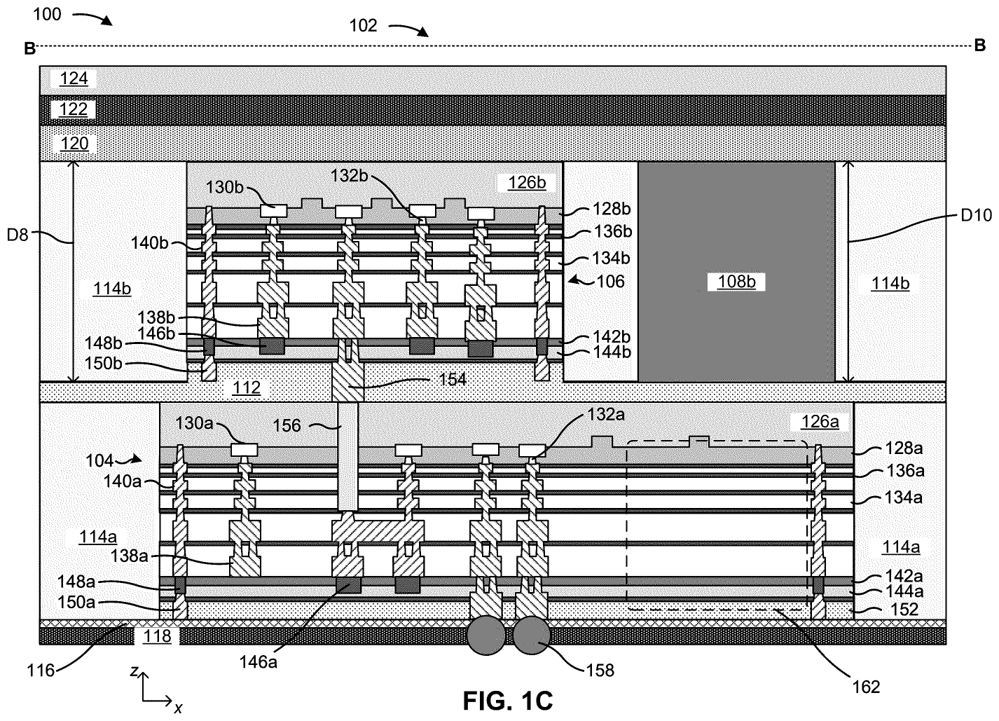

FIGS. 1A-1C are diagrams of an example 100 of a semiconductor die package 102 described herein. The semiconductor die package 102 includes a packaged semiconductor device that includes a plurality of active IC dies or chips. The plurality of active IC dies may be vertically arranged and/or stacked in the semiconductor die package 102 using three-dimensional (3D) packaging techniques such as direct bonding.

FIG. 1A illustrates a top view of the semiconductor die package 102. As shown in FIG. 1A, the semiconductor die package 102 includes an active IC die 104. The active IC die 104 is an IC die that includes active integrated circuits of the semiconductor die package 102 and is configured perform various processing functions of the semiconductor die package 102.

Examples for the active IC die 104 includes a logic IC die, a memory IC die, a high-bandwidth memory (HBM) IC die, an input/output (I/O) die, a system-on-chip (SoC) IC die, a dynamic random access memory (DRAM) IC die, a complementary metal-oxide-semiconductor (CMOS) image sensor IC die, a silicon photonics IC die, a central processing unit (CPU) IC die, a graphics processing unit (GPU) IC die, a digital signal processing (DSP) IC die, an application specific integrated circuit (ASIC) IC die, and/or another type of active IC die.

The active IC die 104 has a plurality of outer edges that correspond to the perimeter of the active IC die 104. The plurality of outer edges may include an outer edge 104a, an outer edge 104b, an outer edge 104c, and an outer edge 104d, among other examples. As shown in the example in FIG. 1A, the active IC die 104 may have an approximately square or rectangular top view shape. Accordingly, the outer edges 104a and 104c may be located on opposing sides of the active IC die 104, the outer edges 104b and 104d may be located on opposing sides of the active IC die 104, the outer edges 104a and 104b may be approximately orthogonal, the outer edges 104a and 104d may be approximately orthogonal, the outer edges 104c and 104b may be approximately orthogonal, and the outer edges 104c and 104d may be approximately orthogonal. However, in other implementations, the active IC die 104 may be approximately circle shaped (or generally round shaped), hexagon shaped, or another shape. Alternatively, the active IC die 104 may include a non-standard shape or an amorphous shape.

As further shown in FIG. 1A, the semiconductor die package 102 further includes an active IC die 106. The active IC die 106 is included on the active IC die 104 such that the active IC dies 104 and 106 are stacked and vertically arranged in a z-direction in the semiconductor die package 102. In some implementations, the active IC die 104 and the active IC die 106 are the same type of active IC die. For example, the active IC die 104 and the active IC die 106 may each be a separate CPU die. In some implementations, the active IC die 104 and the active IC die 106 are different types of active IC dies. For example, the active IC die 104 may be a CPU die, and the active IC die 106 may be an I/O die or an HBM die.

As further shown in FIG. 1A, the top view area of the active IC die 106 is different from the top view area of the active IC die 104. For example, the top view size of the active IC die 104 (e.g., the size of the x-y area occupied by the active IC die 104) may be greater than the top view size of the active IC die 106 (e.g., the size of the x-y area occupied by the active IC die 106). As another example, the top view shape of the active IC die 106 may be different from the top view shape of the active IC die 104. For example, the active IC die 104 may have an approximate square-shaped top view area, whereas the active IC die 106 may have an approximate rectangle-shaped top view area.

The different top view areas of the active IC die 104 and the active IC die 106 results in the active IC die 106 occupying less than the entire top view area of the active IC die 104. This enables a plurality of non-active dies 108a and 108b to be included over and/or on the active IC die 104 over regions of the active IC die 104 that extend laterally outward from the active IC die 106. For example, the non-active dies 108a and 108b may be included between the active IC die 106 and the outer edge 104c of the active IC die 104. Alternatively, one or more of the non-active dies 108a and/or 108b may be located between the active IC die 106 and another outer edge (e.g., the outer edge 104a, the outer edge 104b, the outer edge 104d) of the active IC die 104.

The non-active dies 108a and 108b may each include dies that are passive components and/or dies that do not perform electrical and/or processing functions of the semiconductor die package 102. Examples of non-active dies 108a and 108b include dummy dies, integrated passive device (IPD) dies, dielectric structures (e.g., thick films), and/or other types of non-active dies. A non-active die may also be referred to as an insertion die, a filler die, and/or another type of die that does not perform electrical and/or processing functions of the semiconductor die package 102. An IPD die may include a capacitor or capacitor die, a resistor or resistor die, an inductor or inductor die, or a combination thereof.

The non-active dies 108a and 108b may each be located laterally adjacent to an edge of the active IC die 106. In some implementations, the non-active dies 108a and 108b are located laterally adjacent to a same edge of the active IC die 106. In some implementations, the non-active dies 108a and 108b are located laterally adjacent different edges of the active IC die 106. The non-active dies 108a and the active IC die 106 may be physically touching (e.g., in physical contact with each other) or may be spaced apart by a gap 110. In some implementations, the size of the gap 110 (e.g., the distance between the non-active die 108a and the active IC die 106, indicated in FIG. 1A as dimension D1), is included in a range of approximately 25 microns to approximately 75 microns. If the size of the gap 110 is too small, poor gap filling performance may result when filling in the gap 110 with dielectric material, leading to cracking in the dielectric material in the gap 110. If the size of the gap 110 is too large, not enough space on the active IC die 104 may be provided for the non-active die 108a, leading to reduced structural integrity for the non-active die 108a. If the size of the gap 110 is included in the range of approximately 25 microns to approximately 75 microns, sufficient gap filling performance may be achieved while providing sufficient space for placing the non-active die 108a over and/or on the active IC die 104. However, other values, and ranges other than approximately 25 microns to approximately 75 microns, are within the scope of the present disclosure.

The non-active dies 108b and the active IC die 106 may be physically touching (e.g., in physical contact with each other) or may be spaced apart by a gap 110. In some implementations, the size of the gap 110 (e.g., the distance between the non-active die 108b and the active IC die 106, indicated in FIG. 1A as dimension D2), is included in a range of approximately 25 microns to approximately 75 microns. If the size of the gap 110 is too small, poor gap filling performance may result when filling in the gap 110 with dielectric material, leading to cracking in the dielectric material in the gap 110. If the size of the gap 110 is too large, not enough space on the active IC die 104 may be provided for the non-active die 108b, leading to reduced structural integrity for the non-active die 108b. If the size of the gap 110 is included in the range of approximately 25 microns to approximately 75 microns, sufficient gap filling performance may be achieved while providing sufficient space for placing the non-active die 108a over and/or on the active IC die 104. However, other values, and ranges other than approximately 25 microns to approximately 75 microns, are within the scope of the present disclosure.

In some implementations, the non-active dies 108a and 108b are laterally adjacent and side-by-side to each other. In some implementations, the non-active dies 108a and 108b are not laterally adjacent to each other. In implementations where the non-active dies 108a and 108b are laterally adjacent to each other, the non-active dies 108a and 108b may be physically touching (e.g., in physical contact with each other) or may be spaced apart by a gap 110. In some implementations, the size of the gap 110 (e.g., the distance between the non-active dies 108a and 108b, indicated in FIG. 1A as dimension D3), is included in a range of approximately 25 microns to approximately 75 microns. If the size of the gap 110 is too small, poor gap filling performance may result when filling in the gap 110 with dielectric material, leading to cracking in the dielectric material in the gap 110. If the size of the gap 110 is too large, not enough space over and/or on the active IC die 104 may be provided for the non-active die 108a and/or for the non-active die 108b, leading to reduced structural integrity for the non-active die 108a and/or for the non-active die 108b. If the size of the gap 110 is included in the range of approximately 25 microns to approximately 75 microns, sufficient gap filling performance may be achieved while providing sufficient space for placing the non-active die 108a over and/or on the active IC die 104. However, other values, and ranges other than approximately 25 microns to approximately 75 microns, are within the scope of the present disclosure.

Including two or more non-active dies in the area occupied by the non-active dies 108a and 108b, as opposed to a single non-active die, enables different non-active dies to be included over different areas or regions of the active IC die 104. In particular, this enables different non-active dies to be manufactured to optimize the non-active dies for the attributes of different areas or regions of the active IC die 104. The non-active dies 108a and 108b may include different materials (or different material compositions), have different structural arrangements of layers and/or features, may include different combinations and arrangements of devices, and/or may have different top view sizes and/or shapes, among other examples.

For example, the material(s), size, shape, structural arrangement, and/or another parameter of the non-active die 108a may be configured to tune the heat dissipation properties of the non-active die 108a for thermal management of the area or region of the active IC die 104 under the non-active die 108a and/or to achieve a particular coefficient of thermal expansion (CTE) for the semiconductor die package 102. Similarly, the material(s), size, shape, structural arrangement, and/or another parameter of the non-active die 108b may be configured to tune the heat dissipation properties of the non-active die 108b for thermal management of the area or region of the active IC die 104 under the non-active die 108b and/or to achieve a particular CTE for the semiconductor die package 102. Thus, if the region of the active IC die 104 under the non-active die 108a generates a greater amount of heat than the region of the active IC die 104 under the non-active die 108b during the operation of the semiconductor die package 102, the non-active die 108a may be manufactured to include one or more materials that have greater thermal conductivity than the material(s) of the non-active die 108b. Alternatively, if the region of the active IC die 104 under the non-active die 108a includes integrated circuits for which the operating performance stabilizes at consistent high temperatures, the non-active die 108a may be manufactured to include one or more materials that have lower thermal conductivity than the material(s) of the non-active die 108b if the region of the active IC die 104 under the non-active die 108b includes integrated circuits for which the operating performance degrades at high temperatures.

Moreover, the respective top view sizes, shapes, and/or positioning of the non-active dies 108a and 108b may also be configured such that the non-active dies 108a and 108b to provide thermal management for particular regions of the active IC die 104. For example, the top view size (e.g., a y-direction width indicated in FIG. 1A as dimension D4 and/or an x-direction width indicated in FIG. 1A as dimension D5) and/or shape for the non-active die 108a may be configured to fully cover a power supply region or a high-voltage region of the active IC die 104, and the top view size (e.g., a y-direction width indicated in FIG. 1A as dimension D8 and/or an x-direction width indicated in FIG. 1A as dimension D7) and/or shape for the non-active die 108b may be configured to fully cover an onboard memory region of the active IC die 104.

As another example, the material(s), size, shape, structural arrangement, and/or another parameter of the non-active die 108a may be configured to tune the stiffness of the semiconductor die package 102 in the region of the active IC die 104 under the non-active die 108a. Similarly, the material(s), size, shape, structural arrangement, and/or another parameter of the non-active die 108b may be configured to tune the stiffness of the semiconductor die package 102 in the region of the active IC die 104 under the non-active die 108b. Thus, if the region of the active IC die 104 under the non-active die 108a includes a low density of metallization layers compared to the region of the active IC die 104 under the non-active die 108b, the non-active die 108a may include metallization layers to increase the stiffness of the semiconductor die package 102 in the region of the active IC die 104 under the non-active die 108a.

FIG. 1B illustrates a cross-section view of the semiconductor die package 102 along the line A-A in FIG. 1A. Thus, the cross-section view illustrated in FIG. 1B includes the active IC die 104, the active IC die 106 over and/or on the active IC die 104, and the non-active die 108a over and/or on the active IC die 104 and laterally adjacent to the active IC die 106. As shown in FIG. 1B, the active IC dies 104 and 106 are bonded together at a bonding layer (or bonding film) 112. The bonding layer 112 includes one or more types of materials such as a silicon oxide (SiOₓ) (e.g., silicon dioxide (SiO₂)) and/or another type of dielectric bonding material. The active IC dies 104 and 106 may be directly bonded (e.g., without an intervening interposer or another intervening structure) such that the active IC dies 104 and 106 are stacked and vertically arranged in the z-direction in the semiconductor die package 102.

As further shown in FIG. 1B, the areas around the sides of the active IC die 104 are filled with a dielectric fill layer 114a such that the dielectric fill layer 114a surrounds the active IC die 104, and the areas around the sides of the active IC die 106 and the non-active die 108a (including the gaps 110) are filled with a dielectric fill layer 114b such that the dielectric fill layer 114b surrounds the active IC die 106. The dielectric fill layer 114b may further surround the non-active dies 108a and 108b. The dielectric fill layers 114a and 114b may each include one or more dielectric materials such as a silicon oxide (SiOₓ) (e.g., silicon dioxide (SiO₂)), silicon oxynitride (SiON), and/or another type of dielectric material. The dielectric fill layers 114a and 114b may provide increased stability and electrical isolation for the active IC dies 104 and 106.

The semiconductor die package 102 includes a plurality of passivation layers, including passivation layers 116 and 118 over and/or on a bottom side of the semiconductor die package 102, and passivation layers 120, 122, and 124 over and/or on a top side of the semiconductor die package 102, among other examples. In some implementations, the passivation layers 116, 118, 120, 122, and 124 may each include various types of electrically insulating materials, such as a silicon nitride (SiₓN_{y}), an undoped silicate glass (USG), a silicon oxide (SiOₓ) (e.g., silicon dioxide (SiO₂)), and/or another type of passivation material.

The active IC dies 104 and 106 may each include a substrate (e.g., substrate 126a in the active IC die 104 and substrate 126b in the active IC die 106). The substrates 126a and 126b may each include a silicon (Si) substrate, a substrate formed of a material including silicon, a III-V compound semiconductor material substrate such as gallium arsenide (GaAs), a silicon on insulator (SOI) substrate, or another type of semiconductor substrate.

The active IC dies 104 and 106 may each include a plurality of stacked layers, including an interlayer dielectric (ILD) layer (e.g., an ILD layer 128a on the substrate 126a and an ILD layer 128b on the substrate 126b). The ILD layers 128a and 128b may each include a silicon nitride (SiₓN_{y}), an oxide (e.g., a silicon oxide (SiOₓ) and/or another oxide material), and/or another type of dielectric material.

The active IC dies 104 and 106 may each include IC devices (e.g., IC devices 130a in the substrate 126a and/or in the ILD layer 128a, IC devices 130b in the substrate 126b and/or in the ILD layer 128b). The IC devices 130a and 130b may include front end transistor structures (e.g., front end planar transistor structures, front end fin field effect transistor (finFET) structures, front end gate all around (GAA) transistor structures), pixel sensors, capacitors, resistors, inductors, photodetectors, transceivers, transmitters, receivers, optical circuits, and/or other types of front end semiconductor devices.

The active IC dies 104 and 106 may each include contacts (e.g., contacts 132a, contacts 132b) that are electrically coupled with the IC devices. The contacts 132a may extend through the ILD layer 128a and may be electrically coupled with the IC devices 130a, and the contacts 132b may extend through the ILD layer 128b and may be electrically coupled with the IC devices 130b. The contacts 132a and 132b may include vias, plugs, and/or another type of elongated electrically conductive structures. The contacts 132a and 132b may include tungsten (W), cobalt (Co), ruthenium (Ru), titanium (Ti), aluminum (Al), and/or gold (Au), among other electrically conductive materials.

The active IC dies 104 and 106 may each include a plurality of dielectric layers that are arranged in an alternating manner in the z-direction in the semiconductor die package 102. For example, the active IC die 104 may include a plurality of alternating ILD layers 134a and etch stop layers (ESLs) 136a. The active IC die 104 may include a plurality of conductive structures 138a in the ILD layers 134a and ESLs 136a. The substrate 126a, the ILD layer 128a, the IC devices 130a, and the contacts 132a may correspond to a device layer or front end of line (FEOL) region of the active IC die 104, and the ILD layers 134a, the ESLs 136a, and the conductive structures 138a may correspond to an interconnect layer or back end of line (BEOL) region of the active IC die 104.

Similarly, the active IC die 106 may include a plurality of alternating ILD layers 134b and ESLs 136b. The active IC die 106 may include a plurality of conductive structures 138b in the ILD layers 134b and ESLs 136b. The substrate 126b, the ILD layer 128b, the IC devices 130b, and the contacts 132b may correspond to a device layer or FEOL region of the active IC die 106, and the ILD layers 134b, the ESLs 136b, and the conductive structures 138b may correspond to an interconnect layer or BEOL region of the active IC die 106.

The ILD layers 134a and 134b may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 134a or 134b includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous HSQ, porous methyl silsesquioxane (MSQ), porous polyarylether (PAE), and/or porous silicon oxide (SiOₓ), among other examples. The ESLs 136a and 136b may each include a silicon nitride (SiₓN_{y}), silicon carbide (SiC), silicon oxynitride (SiON), and/or another suitable dielectric material.

The conductive structures 138a and 138b provide electrical routing that enables signals and/or power to be provided to and/or from the IC devices 130a and/or 130b. The conductive structures 138a and 138b may include a combination of trenches, metallization layers, conductive traces, vias, interconnects, and/or other types of conductive structures. The conductive structures 138a and 138b may each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

The active IC die 104 may further include a seal ring structure 140a around the conductive structures 138a to protect the active IC die 104 from physical and/or electrical damage during a dicing operation to cut the active IC die 104 from a wafer. The seal ring structure 140a may further provide protection from humidity ingress and other contaminants. The active IC die 106 may similarly include a seal ring structure 140b around the conductive structures 138b to protect the active IC die 106 from physical and/or electrical damage during a dicing operation to cut the active IC die 106 from a wafer. The seal ring structure 140b may further provide protection from humidity ingress and other contaminants.

The active IC die 104 may include passivation layers 142a and 144a over and/or on the plurality of alternating dielectric layers (e.g., the ILD layers 134a and the ESLs 136a) to passivate the interconnect layer of the active IC die 104. Similarly, the active IC die 106 may include passivation layers 142b and 144b over and/or on the plurality of alternating dielectric layers (e.g., the ILD layers 134b and the ESLs 136b) to passivate the interconnect layer of the active IC die 106.

Metal pads 146a may be included over and/or on the conductive structures 138a, and metal pads 148a may be included over and/or on the seal ring structure 140a. Metal pads 146b may be included over and/or on the conductive structures 138b, and metal pads 148b may be included over and/or on the seal ring structure 140b. The metal pads 146a, 148a, 146b, and 148b may each include aluminum (Al), aluminum copper (AlCu), and/or another conductive material. The seal ring structures 140a and 140b may further include bonding pads 150a and 150b, respectively. Alternatively the bonding pads 150a and/or 150b may be omitted. The bonding pads 150a and 150b may each include tungsten (W), cobalt (Co), ruthenium (Ru), titanium (Ti), aluminum (Al), copper (Cu), gold (Au), and/or a combination thereof, among other examples of electrically conductive materials.

The active IC die 104 further includes a bonding layer 152, which is used to bond the active IC die 104 to a carrier substrate during manufacturing of the semiconductor die package 102. The bonding layer 152 includes one or more types of materials such as a silicon oxide (SiOₓ) (e.g., silicon dioxide (SiO₂)) and/or another type of dielectric bonding material.

The active IC die 106 may further include bonding pads 154 that enable the active IC die 106 to be bonded to a die-to-die interconnect 156 of the active IC die 104. The bonding pads 154 may each include tungsten (W), cobalt (Co), ruthenium (Ru), titanium (Ti), aluminum (Al), copper (Cu), gold (Au), and/or a combination thereof, among other examples of electrically conductive materials. The die-to-die interconnect 156 may include a die-to-die wire, a through substrate via (TSV), or another type of die-to-die interconnect. The die-to-die interconnect 156 also electrically connects the active IC dies 104 and 106. In this way, electrical signals and/or power may be provided between the active IC dies 104 and 106 through the die-to-die interconnect 156. The die-to-die interconnect 156 includes a conductive material such as tungsten (W), cobalt (Co), ruthenium (Ru), titanium (Ti), aluminum (Al), copper (Cu), gold (Au), and/or a combination thereof, among other examples of conductive materials.

As further shown in FIG. 1B, the topmost layer of conductive structures 138a (e.g., a top metal layer) may be coupled to connection structures 158 at the top of the semiconductor die package 102 (which is facing downward in FIG. 1B). The connection structures 158 may include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures that enable the semiconductor die package 102 to be connected to a substrate or a socket, among other examples.

As further shown in FIG. 1B, the non-active die 108a is located laterally adjacent to the active IC die 106, and is located above a portion 160 of the active IC die 104. The non-active die 108a may be located over and/or on (and in some implementations, bonded to) the bonding layer 112. As described above, the non-active die 108a may be manufactured to include a combination of materials, a size, a shape, a combination of structures and/or layers, and/or other properties and/or attributes to provide thermal management and/or structural management for the portion 160 of the active IC die 104 that is located under the non-active die 108a. In the example illustrated in FIG. 1B, the portion 160 of the active IC die 104 may include a high density of IC devices 130a, and therefore a large amount of heat may be generated in the portion 160 of the active IC die 104. Thus, in the example in FIG. 1B, the non-active die 108a may include one or more materials having high thermal conductivity such as silicon (Si), graphite or graphene, and/or another material having high thermal conductivity. The high thermal conductivity enables the non-active die 108a to conduct heat away from the portion 160 of the active IC die 104, thereby reducing and/or stabilizing the operating temperature in the portion 160 of the active IC die 104.

As further shown in FIG. 1B, the active IC die 106 may have a z-direction thickness (indicated in FIG. 1B as dimension D8) and the non-active die 108a may have a z-direction thickness (indicated in FIG. 1B as dimension D9). In some implementations, the z-direction thicknesses of the active IC die 106 and the non-active die 108a are approximately the same z-direction thickness such that the back side of the substrate 126b and the top of the non-active die 108b are approximately co-planar. This provides a flat substrate on which the passivation layer 120 may be formed. However, in other implementations, the z-direction thicknesses of the active IC die 106 and the non-active die 108a may be different z-direction thicknesses. For example, the difference between the z-direction thickness of the active IC die 104 and the z-direction thickness of the non-active die 108a may be greater than 0 microns and up to 1 micron or greater in some implementations.

FIG. 1C illustrates a cross-section view of the semiconductor die package 102 along the line B-B in FIG. 1A. Thus, the cross-section view illustrated in FIG. 1C includes the active IC die 104, the active IC die 106 over and/or on the active IC die 104, and the non-active die 108b over and/or on the active IC die 104 and laterally adjacent to the active IC die 106.

As shown in FIG. 1C, the non-active die 108b is located laterally adjacent to the active IC die 106, and is located above a portion 162 of the active IC die 104. The non-active die 108b may be located over and/or on (and in some implementations, bonded to) the bonding layer 112. As described above, the non-active die 108b may be manufactured to include a combination of materials, a size, a shape, a combination of structures and/or layers, and/or other properties and/or attributes to provide thermal management and/or structural management for the portion 162 of the active IC die 104 that is located under the non-active die 108b. In the example illustrated in FIG. 1C, the portion 162 of the active IC die 104 may include a low density of IC devices 130a, and therefore a small amount of heat may be generated in the portion 162 of the active IC die 104. Thus, in the example in FIG. 1C, the non-active die 108b may include one or more materials having low thermal conductivity such as silicon oxide (SiOₓ such as SiO₂), silicon nitride (SiₓN_{y} such as Si₃N₄), silicon oxynitride (SiON), and/or another material having low thermal conductivity. The low thermal conductivity enables the non-active die 108b to provide structural stability in the semiconductor die package 102 with minimal expansion and contraction due to heat.

As further shown in FIG. 1C, the non-active die 108b may have a z-direction thickness (indicated in FIG. 1C as dimension D10). In some implementations, the z-direction thicknesses of the active IC die 106 (dimension D8) and the non-active die 108b are approximately the same z-direction thickness such that the back side of the substrate 126b and the top of the non-active die 108b are approximately co-planar. This provides a flat substrate on which the passivation layer 120 may be formed. However, in other implementations, the z-direction thicknesses of the active IC die 106 and the non-active die 108b may be different z-direction thicknesses. For example, the difference between the z-direction thickness of the active IC die 104 and the z-direction thickness of the non-active die 108b may be greater than 0 microns and up to 1 micron or greater in some implementations.

As indicated above, FIGS. 1A-1C are provided as an example. Other examples may differ from what is described with regard to FIGS. 1A-1C.

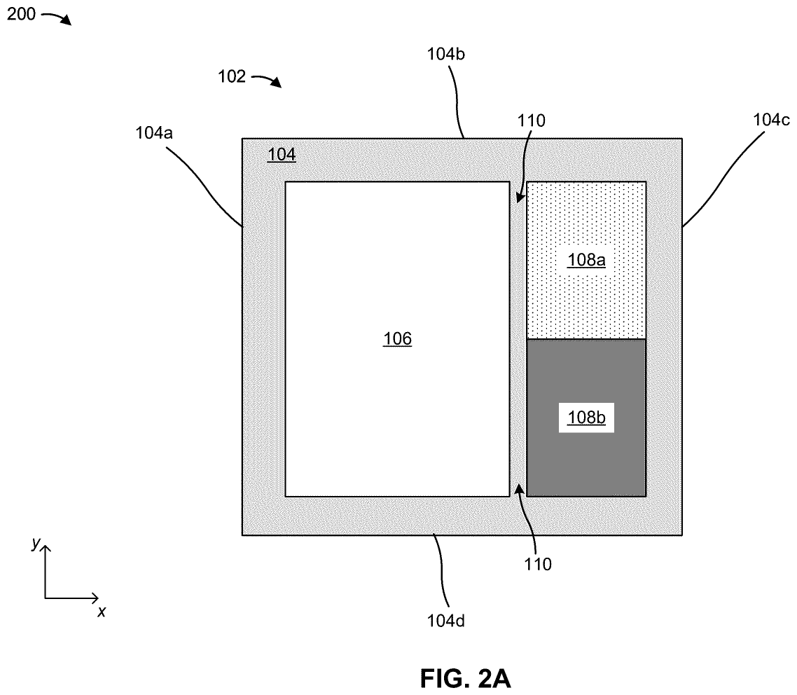

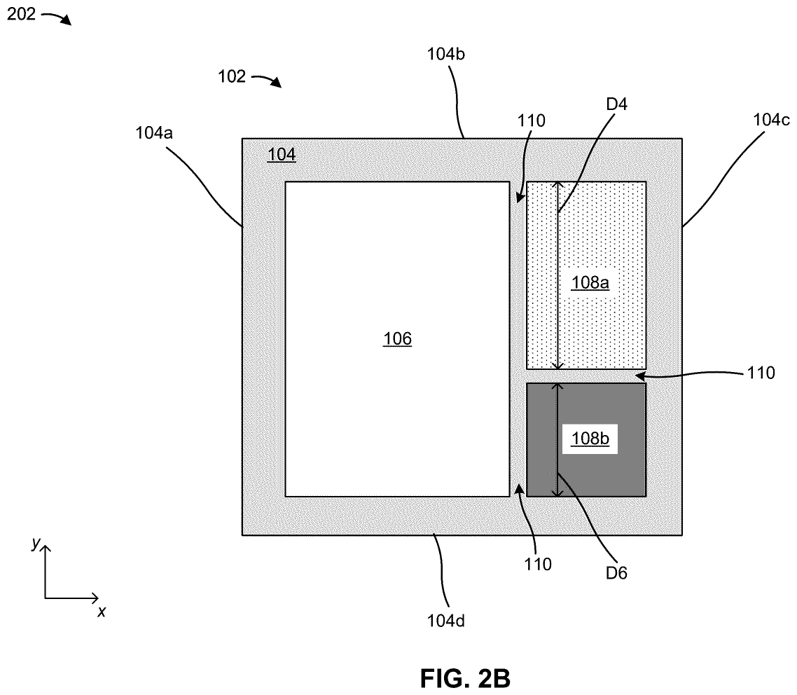

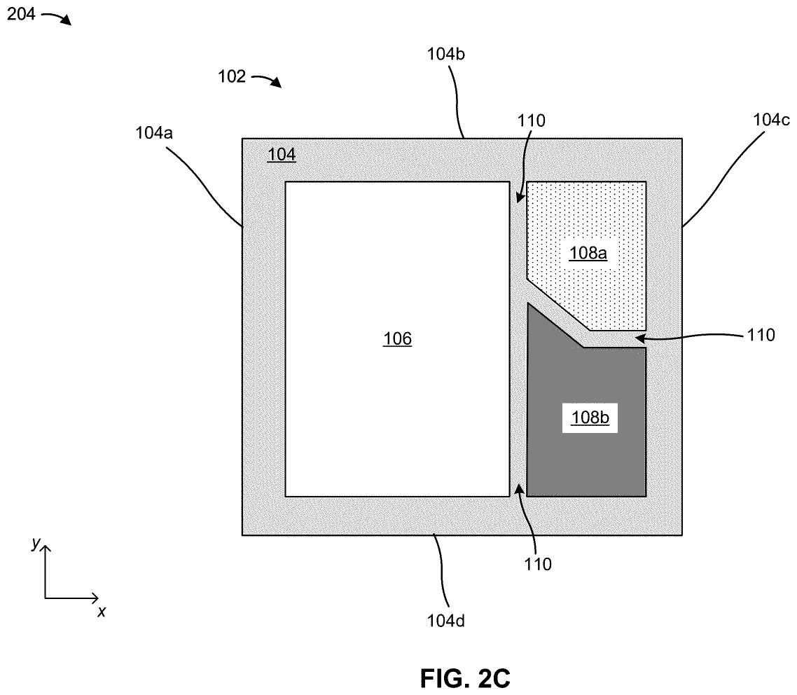

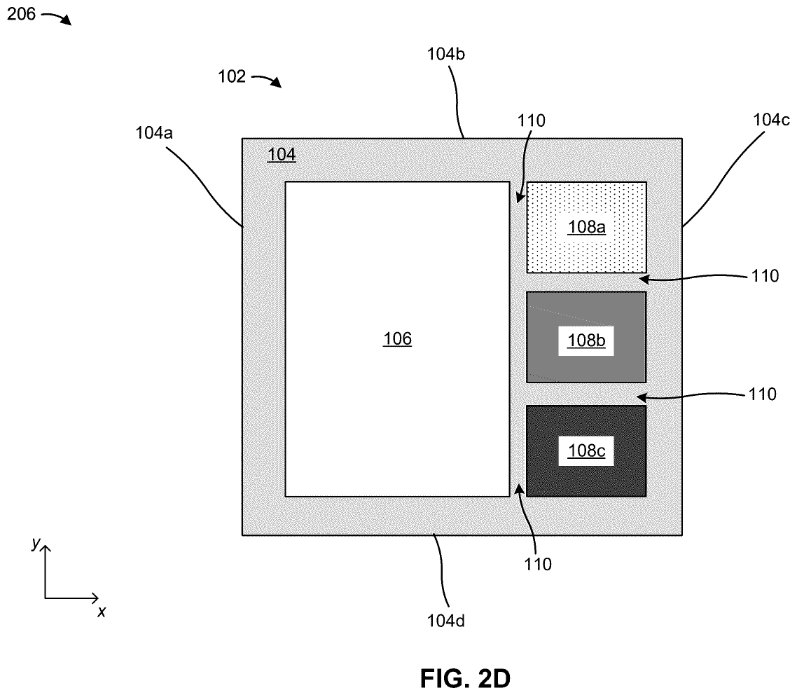

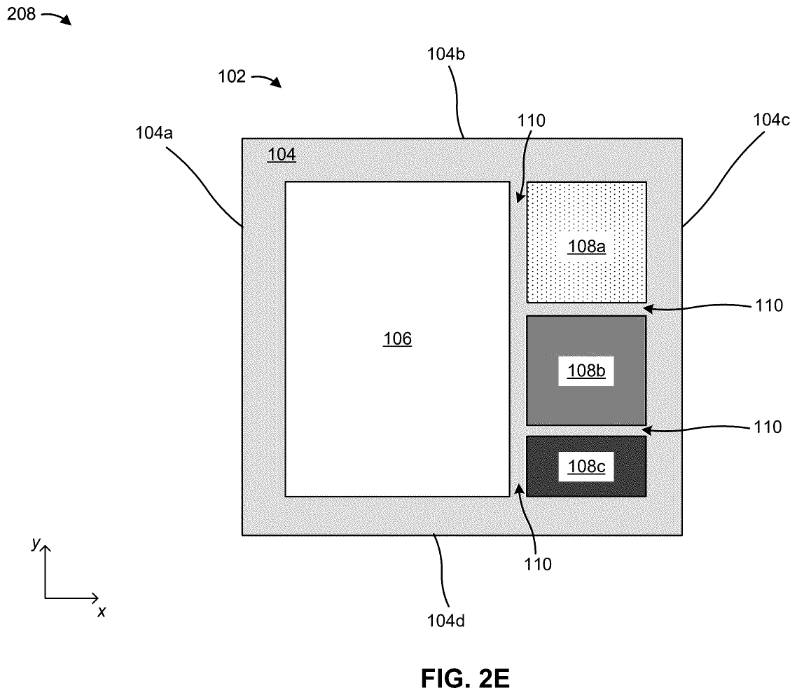

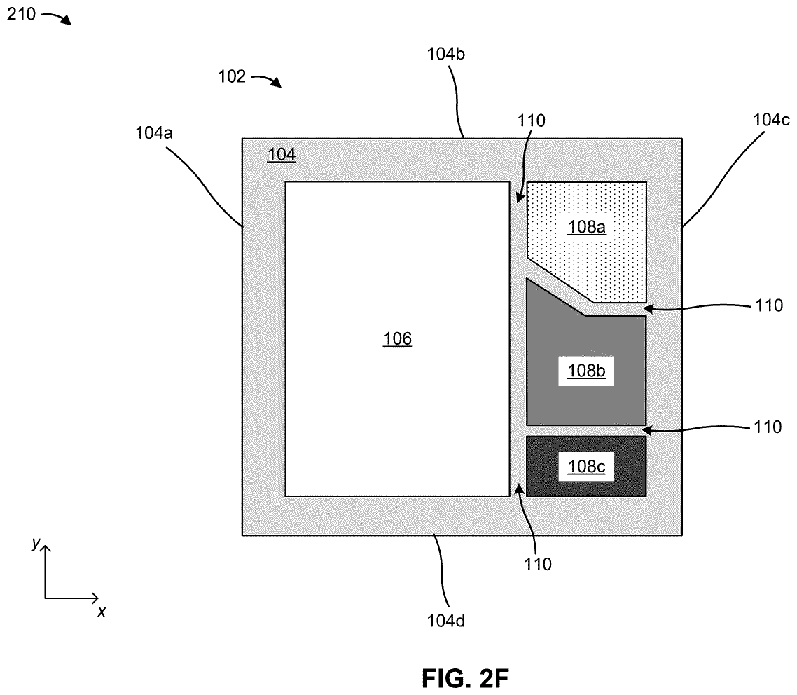

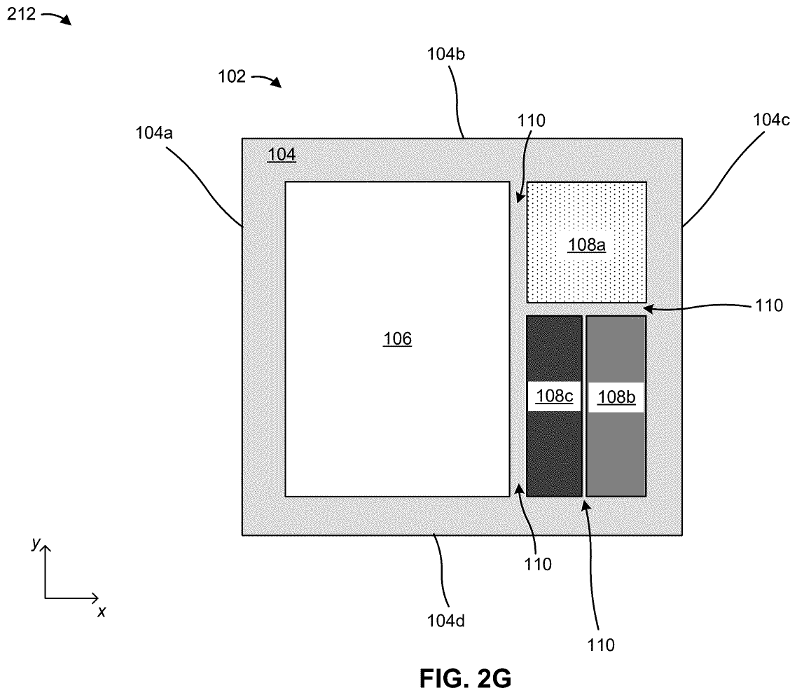

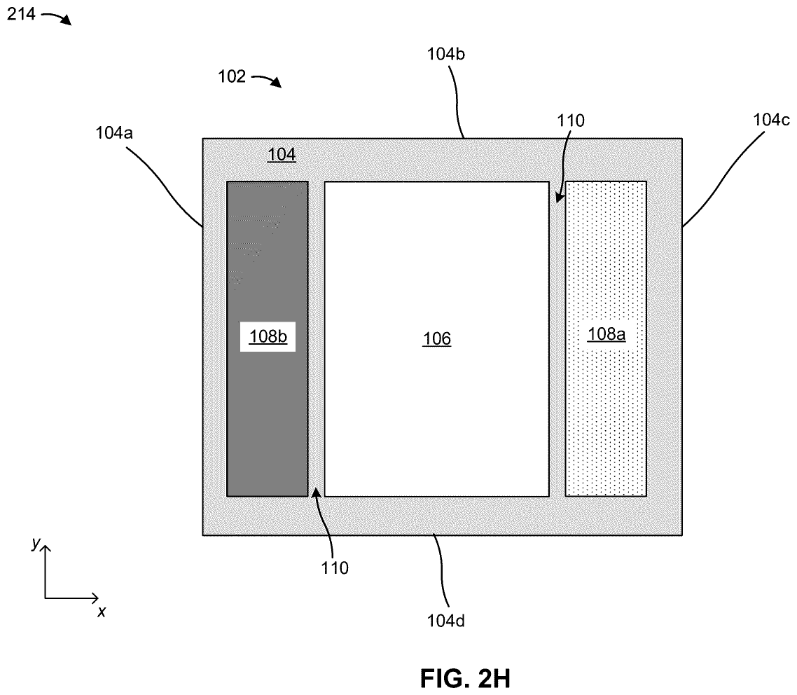

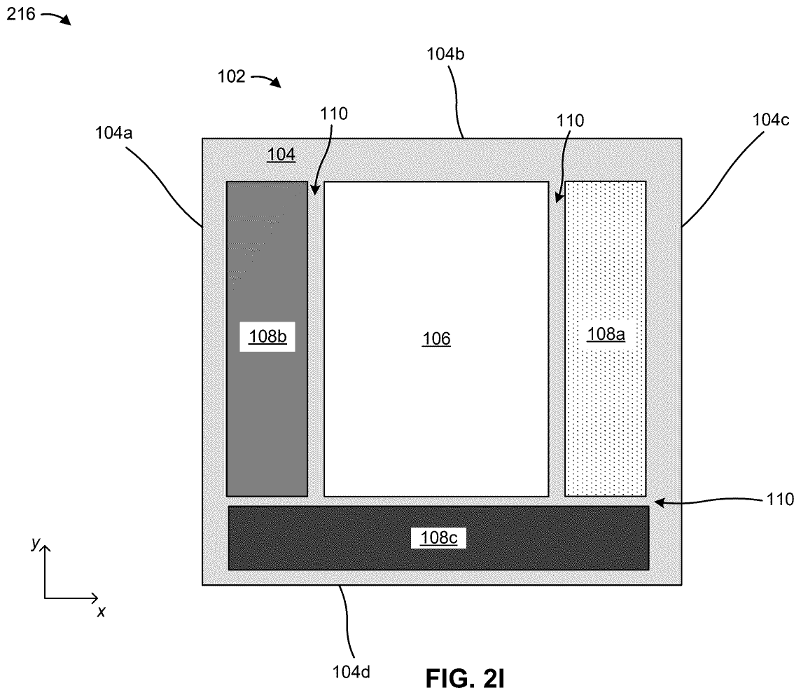

FIGS. 2A-2I are diagrams of examples of top view layouts for non-active dies in a semiconductor die package described herein. While the examples of top view layouts for non-active dies are illustrated in connection with the semiconductor die package 102 in FIGS. 2A-2I, the examples of top view layouts for non-active dies may be implemented in other semiconductor die packages, including semiconductor die packages 402, 502, and/or 602 described herein, among other examples.

As shown in FIG. 2A, an example 200 of a top view layout for non-active dies in a semiconductor die package includes a similar top view layout as illustrated in FIG. 1A, except that the non-active dies 108a and 108b are in physical contact along adjacent edges that are approximately orthogonal to the edges of non-active dies 108a and 108b that are adjacent to the active IC die 106. In the example 200, the non-active die 108a may include a semiconductor die (e.g., a silicon dummy die) and the non-active die 108b may include a dielectric layer (e.g., a dielectric thick film) that is deposited next to the non-active die 108a such that the dielectric layer is in contact with the semiconductor die.

As shown in FIG. 2B, an example 202 of a top view layout for non-active dies in a semiconductor die package includes a similar top view layout as illustrated in FIG. 1A, except that the non-active dies 108a and 108b have different top view sizes. The non-active dies 108a and 108b may have different top view sizes to cover differently sized functional regions of the underlying active IC die 104. In the example 202, the y-direction width (dimension D4) of the non-active die 108a is greater than the y-direction width (dimension D6) of the non-active die 108b.

As shown in FIG. 2C, an example 204 of a top view layout for non-active dies in a semiconductor die package includes a similar top view layout as illustrated in FIG. 1A, except that the non-active dies 108a and 108b have different top view shapes. Moreover, the non-active dies 108a and 108b may have non-standard polygonal top view shapes to cover differently sized and/or shaped functional regions of the underlying active IC die 104. Additionally and/or alternatively, the non-active dies 108a and/or 108b may have curved shapes (e.g., a curved standard shape such as a circle or an oval, a curved non-standard shape) or curved portions.

As shown in FIG. 2D, an example 206 of a top view layout for non-active dies in a semiconductor die package includes a similar top view layout as illustrated in FIG. 1A, except that another non-active die 108c is included on a region or portion of the active IC die 104. Other quantities of non-active dies are also within the scope of the present disclosure. Increasing the quantity of non-active dies, such as in the example 206 in FIG. 2D, enables increased flexibility in tuning the non-active dies for different portions or regions of the active IC die 104, thereby increasing the thermal management performance and/or structural integrity of the semiconductor die package 102.

As shown in FIG. 2E, an example 208 of a top view layout for non-active dies in a semiconductor die package includes a similar top view layout as illustrated in FIG. 2D, except that two or more of the non-active dies 108a-108c have different top view sizes as opposed to approximately the same top view sizes in the example 206 in FIG. 2D. For example, the y-direction width and/or the x-direction width of the non-active die 108a may be greater than the y-direction width and/or the x-direction width of the non-active die 108b. As another example, the y-direction width and/or the x-direction width of the non-active die 108b may be greater than the y-direction width and/or the x-direction width of the non-active die 108c. As another example, the size of the top view area occupied by the non-active die 108a may be greater than the size of the top view area occupied by the non-active die 108b. As another example, the size of the top view area occupied by the non-active die 108b may be greater than the size of the top view area occupied by the non-active die 108c.

As shown in FIG. 2F, an example 210 of a top view layout for non-active dies in a semiconductor die package includes a similar top view layout as illustrated in FIG. 2E, except that the non-active dies 108a and 108b have different top view shapes. Moreover, the non-active dies 108a and 108b may have non-standard polygonal top view shapes to cover differently sized and/or shaped functional regions of the underlying active IC die 104. Additionally and/or alternatively, the non-active dies 108a and/or 108b may have curved shapes (e.g., a curved standard shape such as a circle or an oval, a curved non-standard shape) or curved portions. In some implementations, the non-active dies 108a and 108c have different top view shapes and/or each have non-standard shapes. In some implementations, the non-active dies 108b and 108c have different top view shapes and/or each have non-standard shapes. In some implementations, the non-active dies 108a-108c have different top view shapes and/or each have non-standard shapes.

As shown in FIG. 2G, an example 212 of a top view layout for non-active dies in a semiconductor die package includes a similar top view layout as illustrated in FIG. 2D, except that two or more of the non-active dies 108a-108c are arranged in the x-direction as opposed to the non-active dies 108a-108c all being arranged in the y-direction in the example 206 in FIG. 2D. Other combinations of x-direction arrangement and/or y-direction arrangement are within the scope of the present disclosure, and enable increased flexibility in tuning the non-active dies for different portions or regions of the active IC die 104, thereby increasing the thermal management performance and/or structural integrity of the semiconductor die package 102.

As shown in FIG. 2H, an example 214 of a top view layout for non-active dies in a semiconductor die package includes a similar top view layout as illustrated in FIG. 1A, except that the non-active dies 108a and 108b are located laterally adjacent to different sides of the active IC die 106. For example, the non-active die 108a may be located laterally between a first side of the active IC die 106 and an outer edge 104c of the active IC die 104, and the non-active die 108b may be located laterally between a second side of the active IC die 106 and an outer edge 104a of the active IC die 104. Thus, in the example 214, the non-active dies 108a and 108b are located laterally adjacent to opposing sides of the active IC die 106. However, in other examples, the non-active dies 108a and 108b may be located laterally adjacent to orthogonal sides of the active IC die 106.

As shown in FIG. 2I, an example 216 of a top view layout for non-active dies in a semiconductor die package includes a similar top view layout as illustrated in FIG. 2I, except that another non-active die 108c is included laterally adjacent to a side of the active IC die 106. For example, the non-active die 108a may be located laterally between a first side of the active IC die 106 and an outer edge 104c of the active IC die 104, the non-active die 108b may be located laterally between a second side of the active IC die 106 and an outer edge 104a of the active IC die 104, and the non-active die 108c may be located laterally between a third side of the active IC die 106 and an outer edge 104d of the active IC die 104. Thus, in the example 216, the non-active dies 108a and 108b are located laterally adjacent to opposing sides of the active IC die 106, and the non-active die 108c is located laterally adjacent to the sides of the active IC die 106 adjacent to width the non-active dies 108a and 108b are located.

As indicated above, FIGS. 2A-2I are provided as examples. Other examples may differ from what is described with regard to FIGS. 2A-2I.

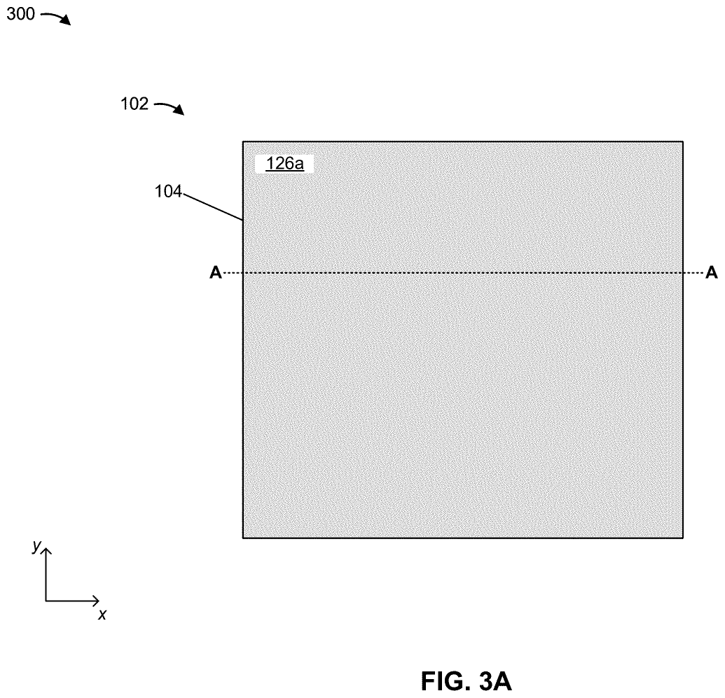

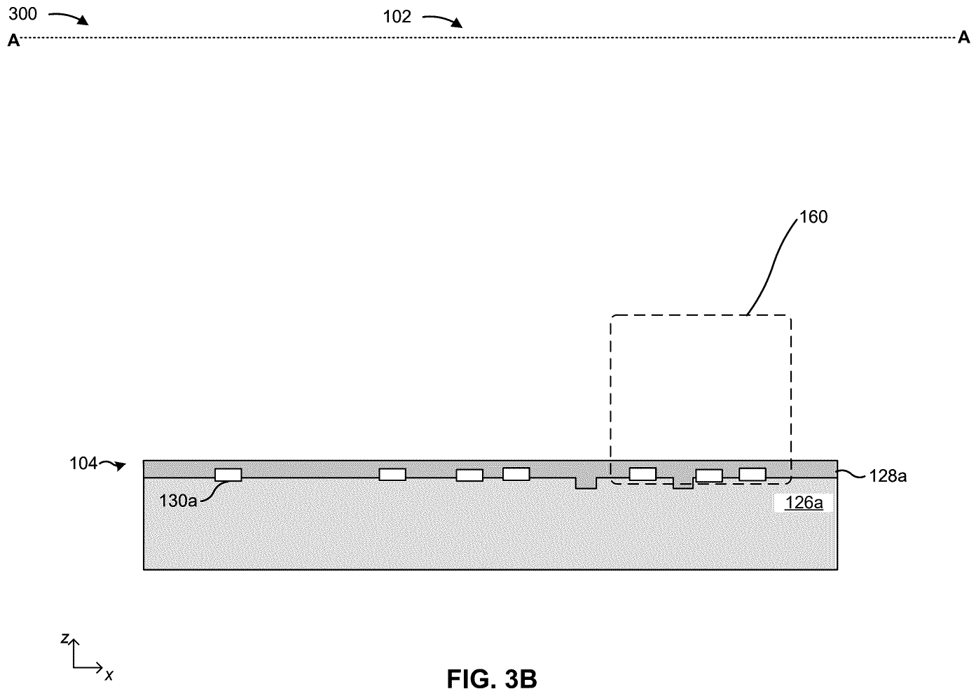

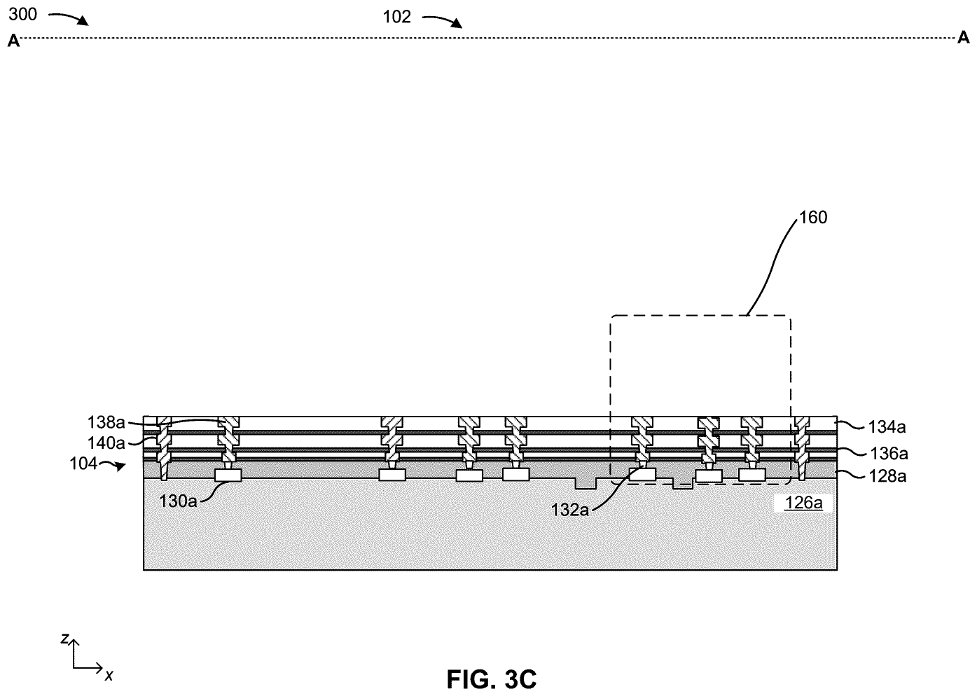

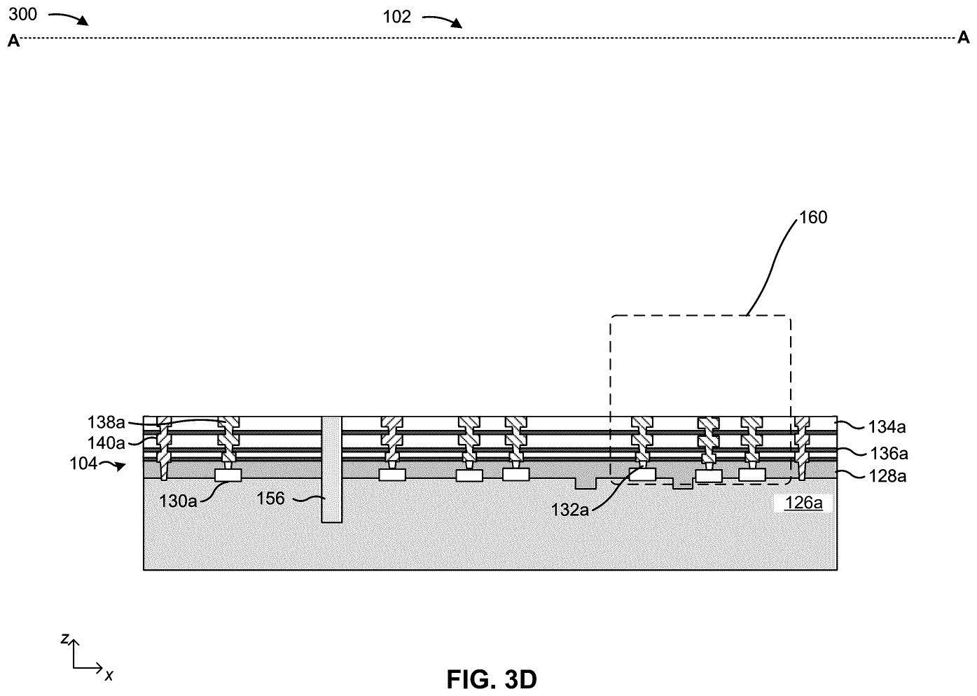

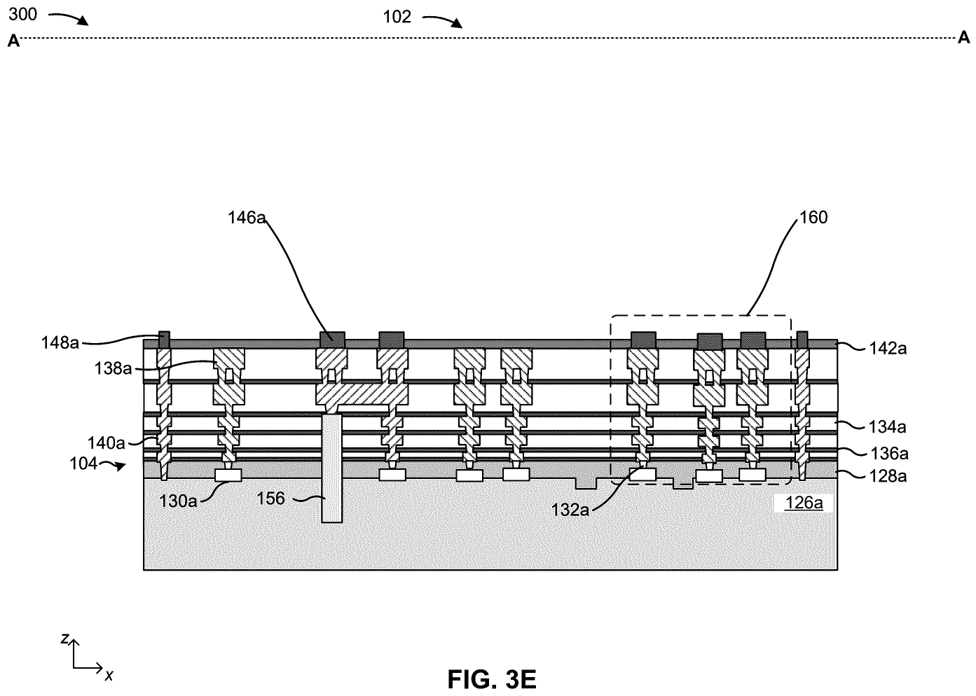

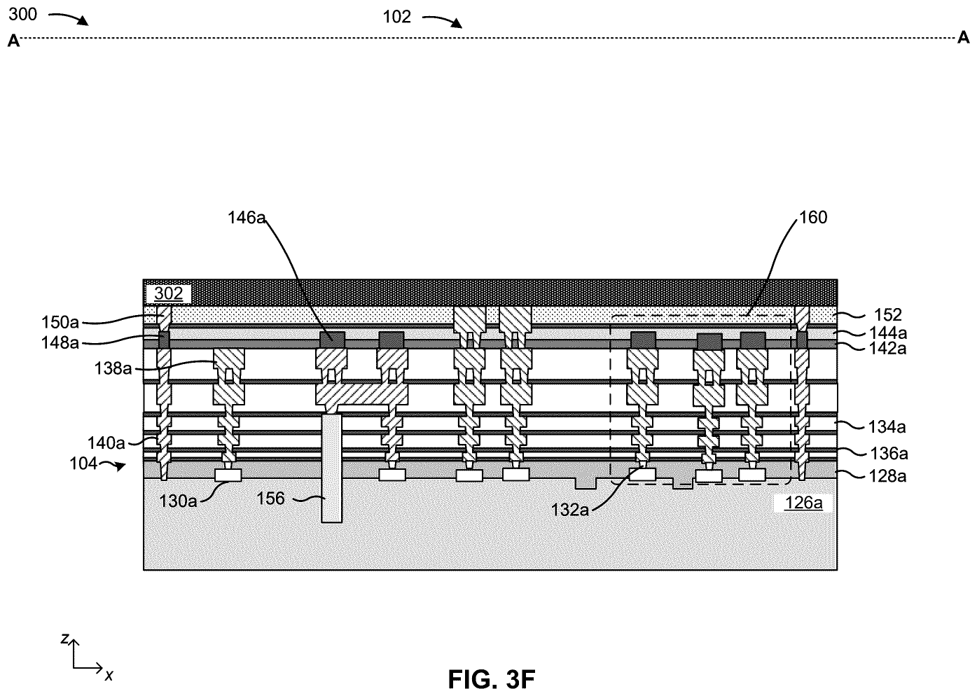

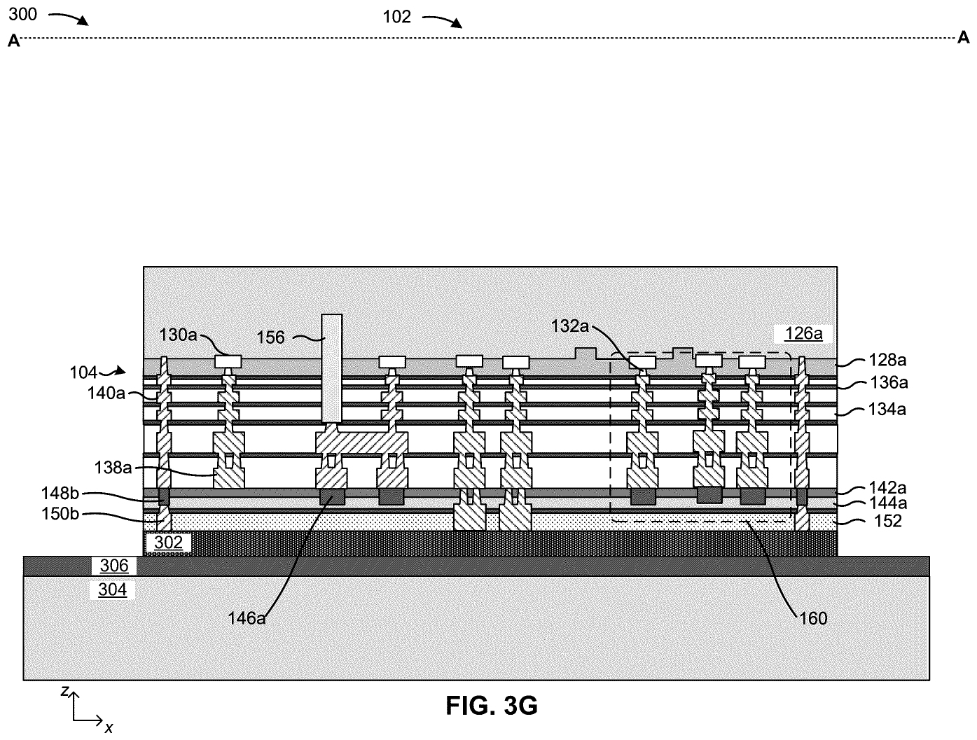

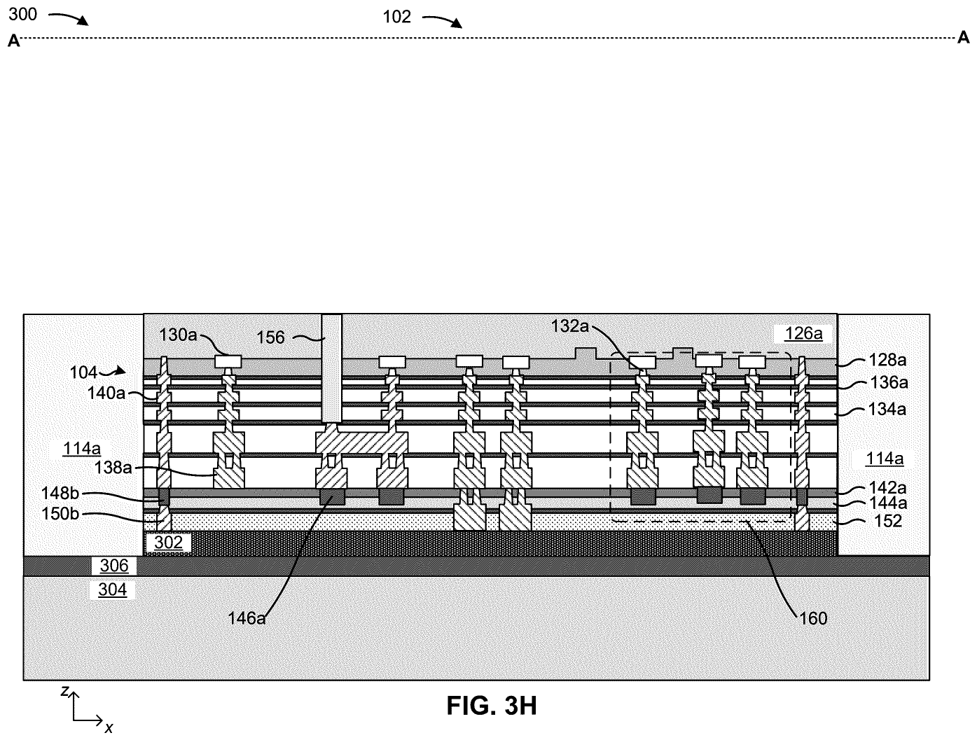

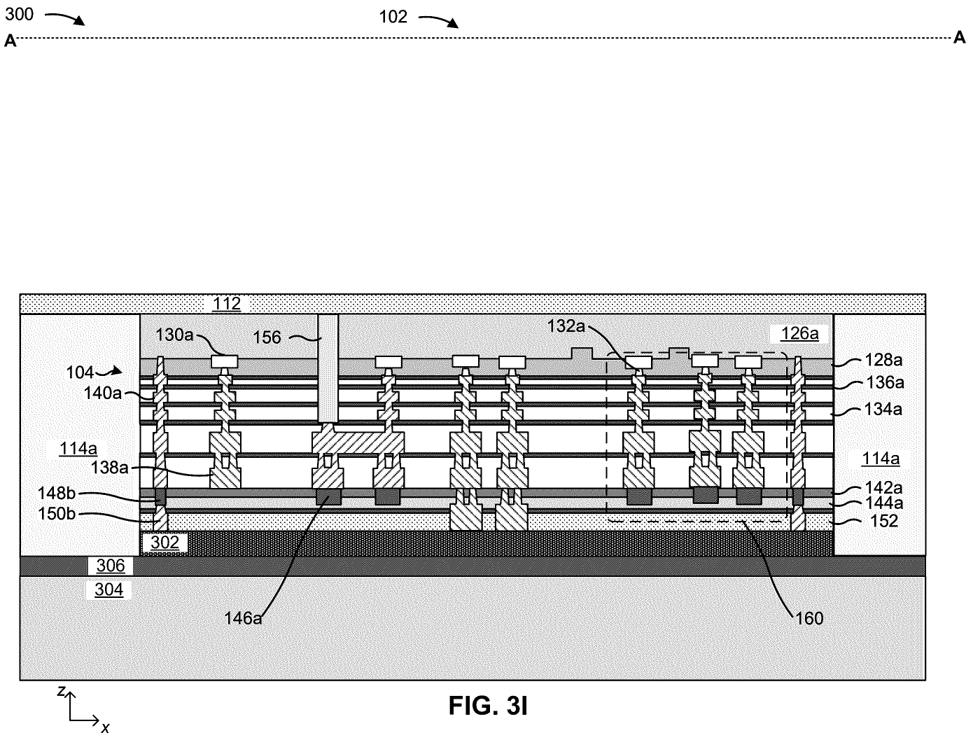

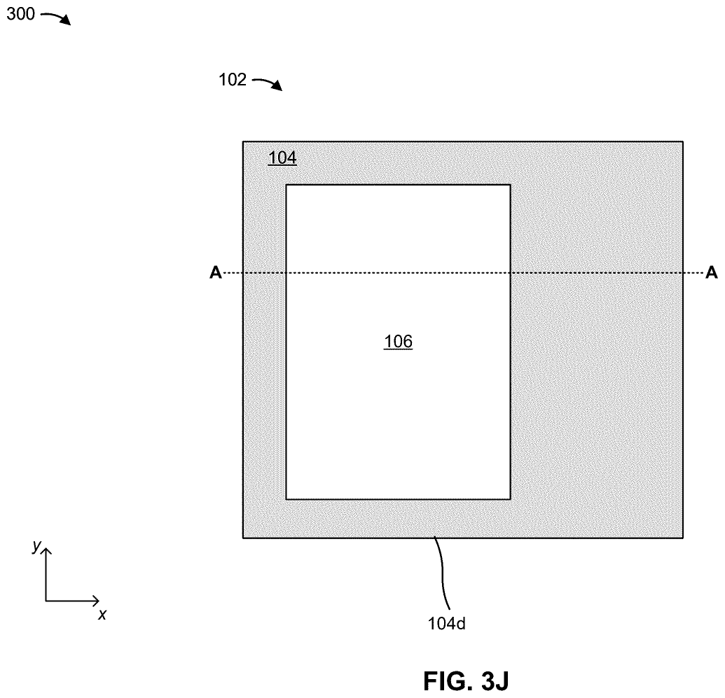

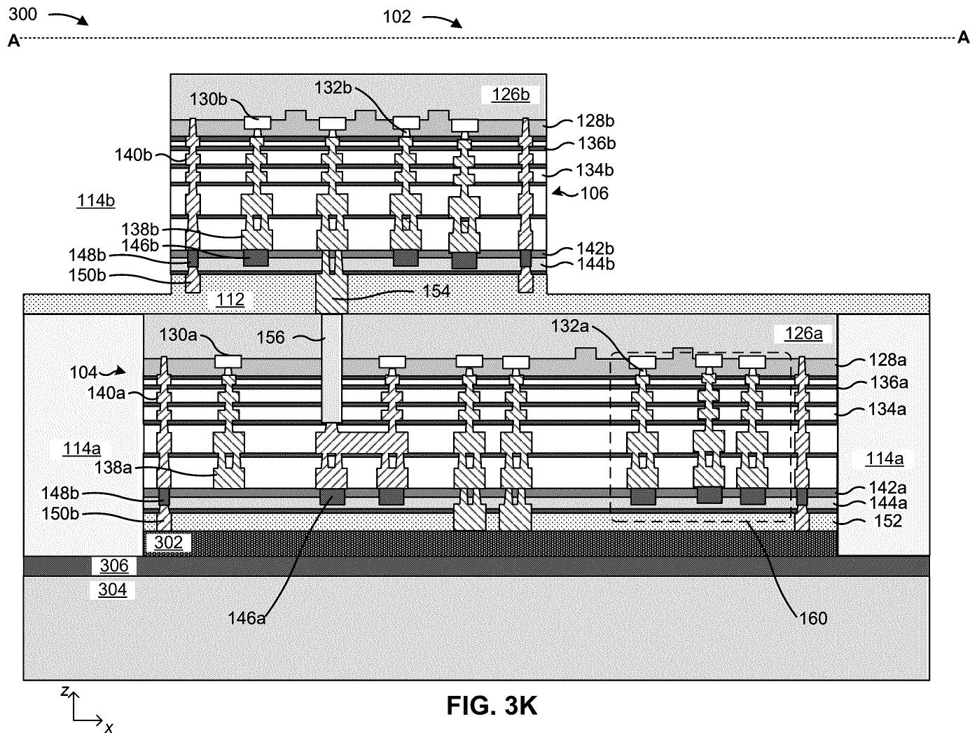

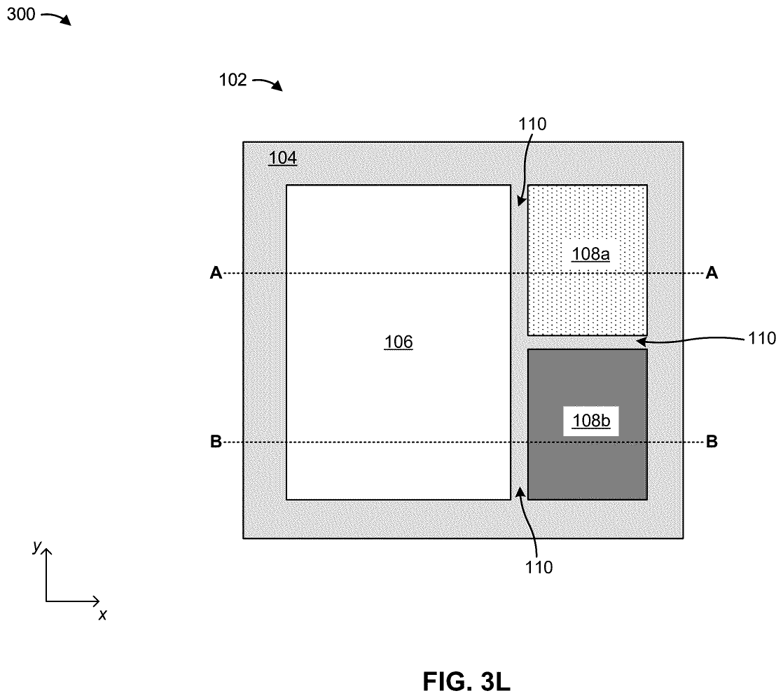

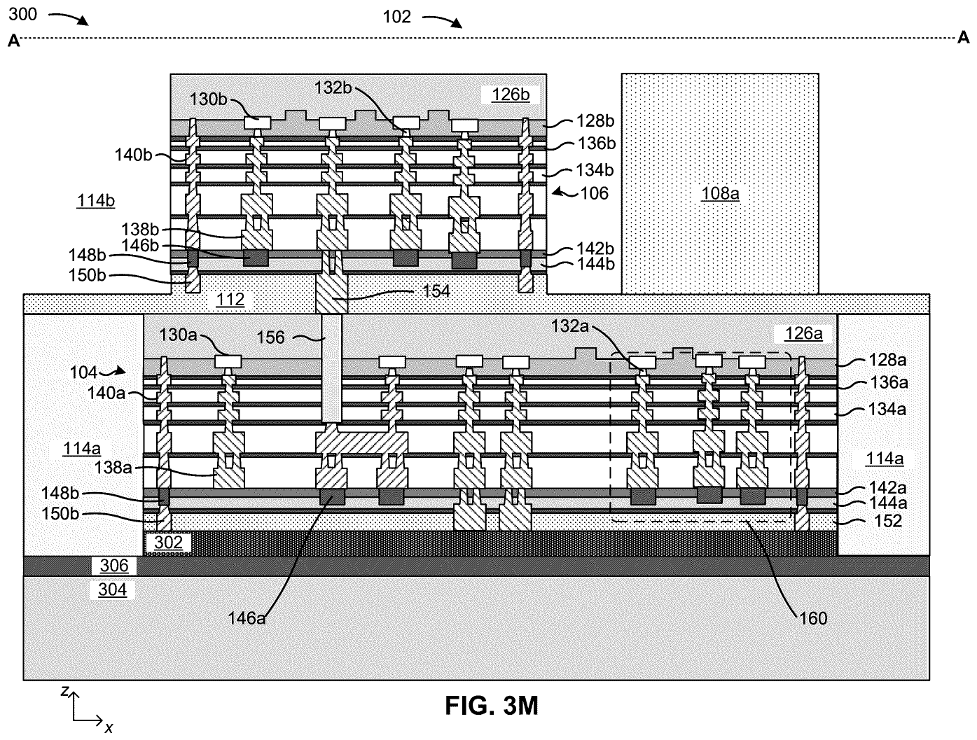

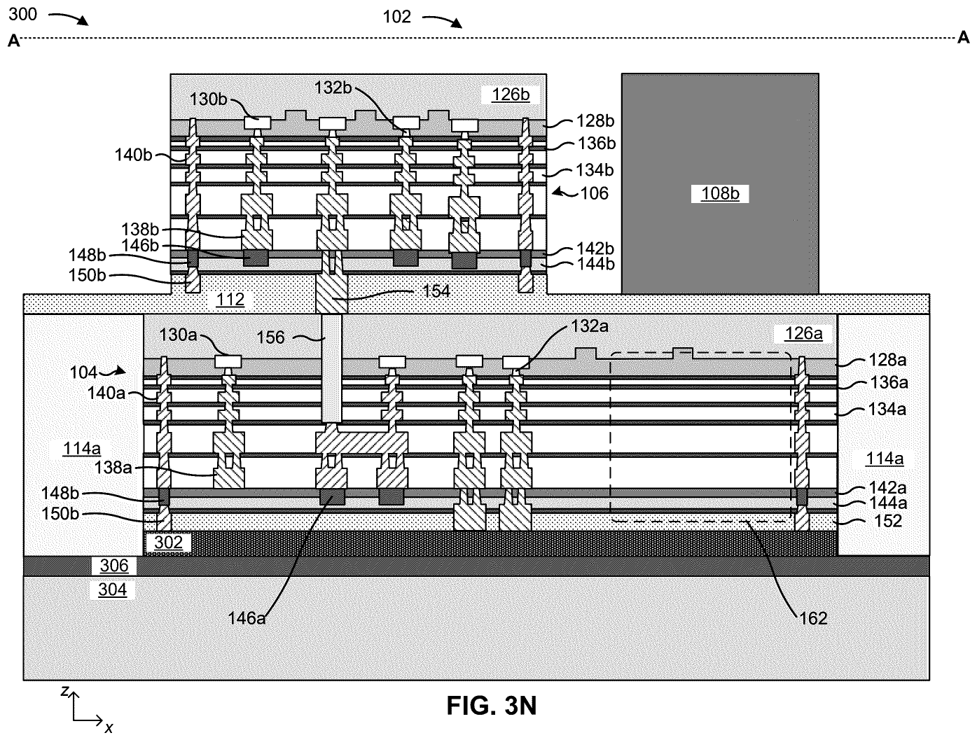

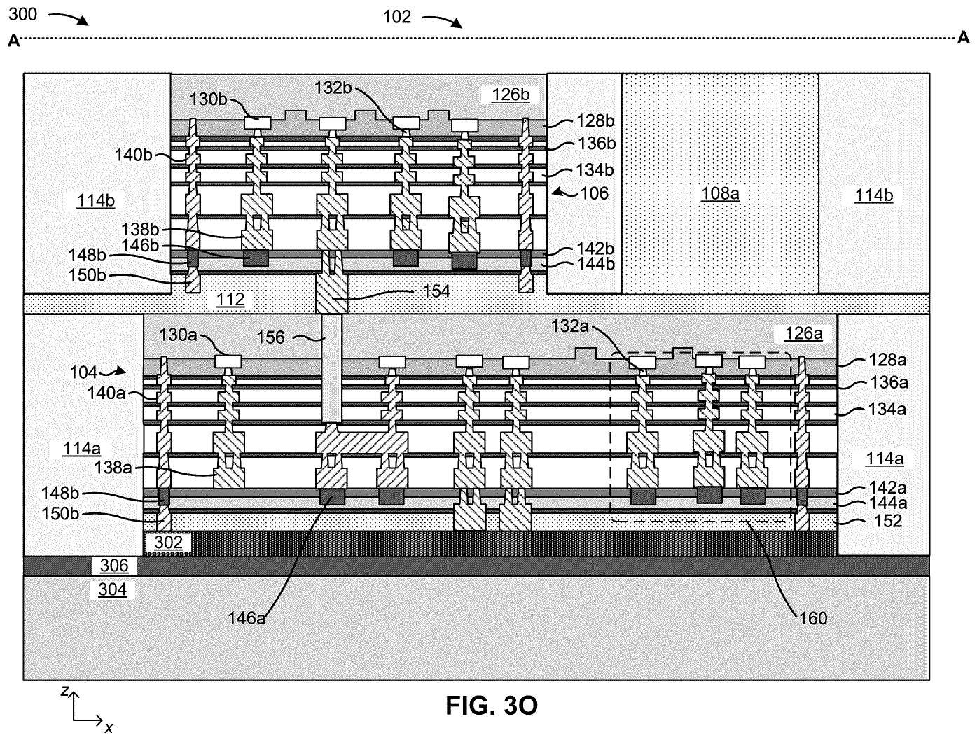

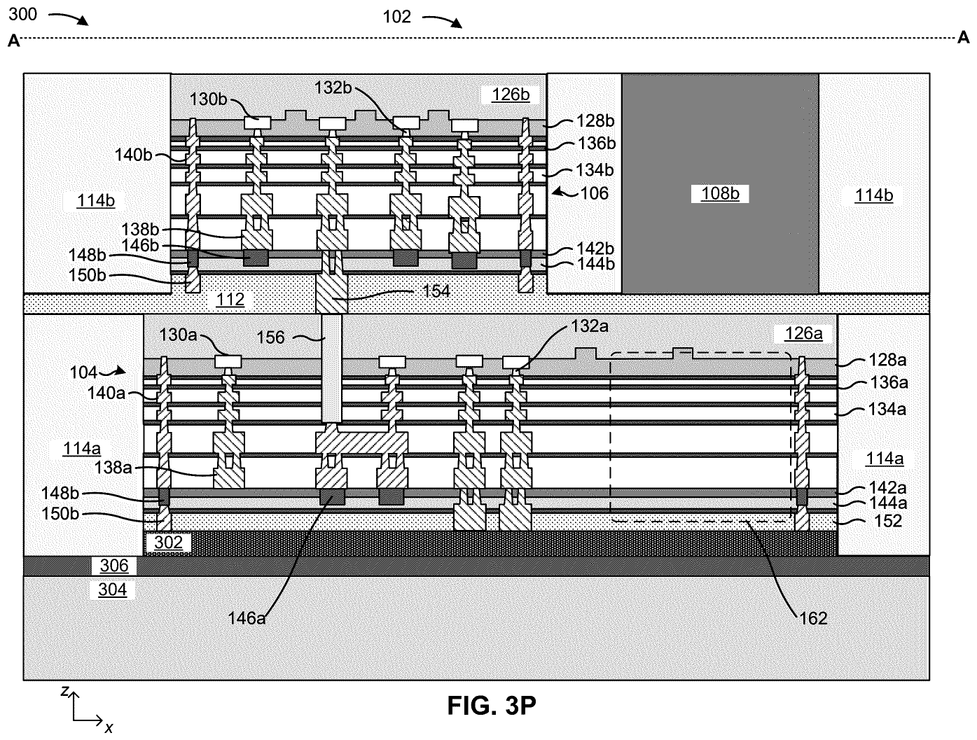

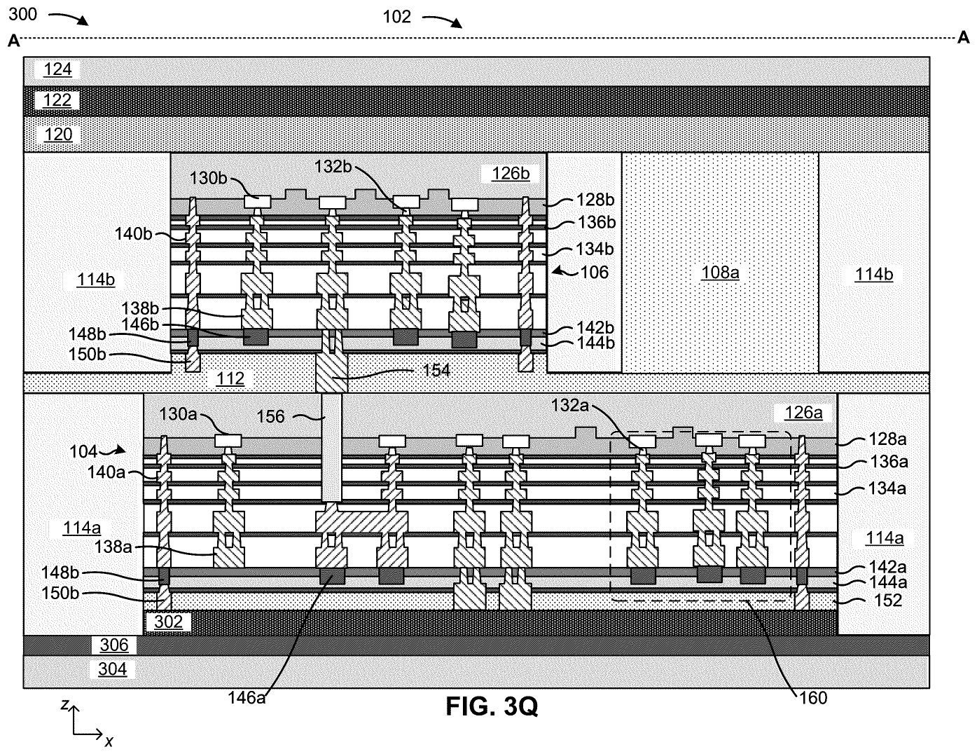

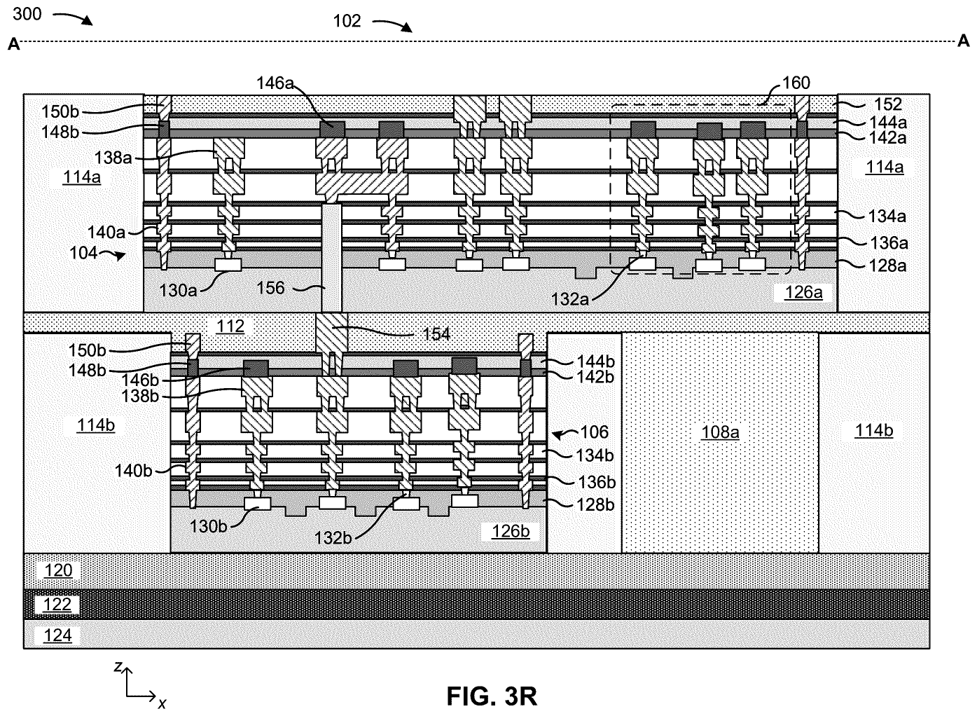

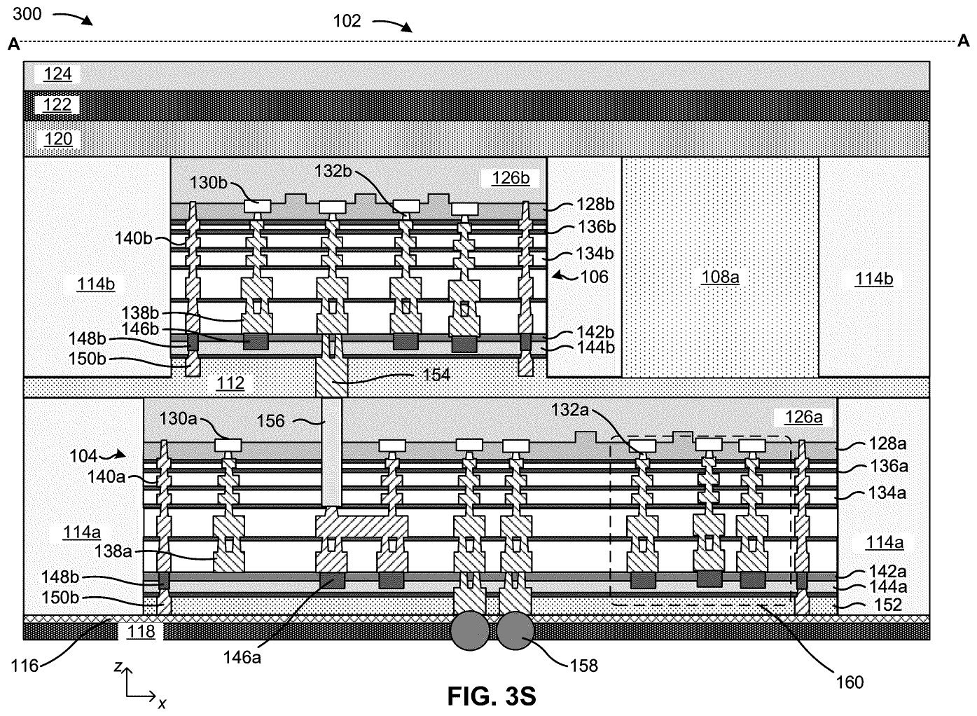

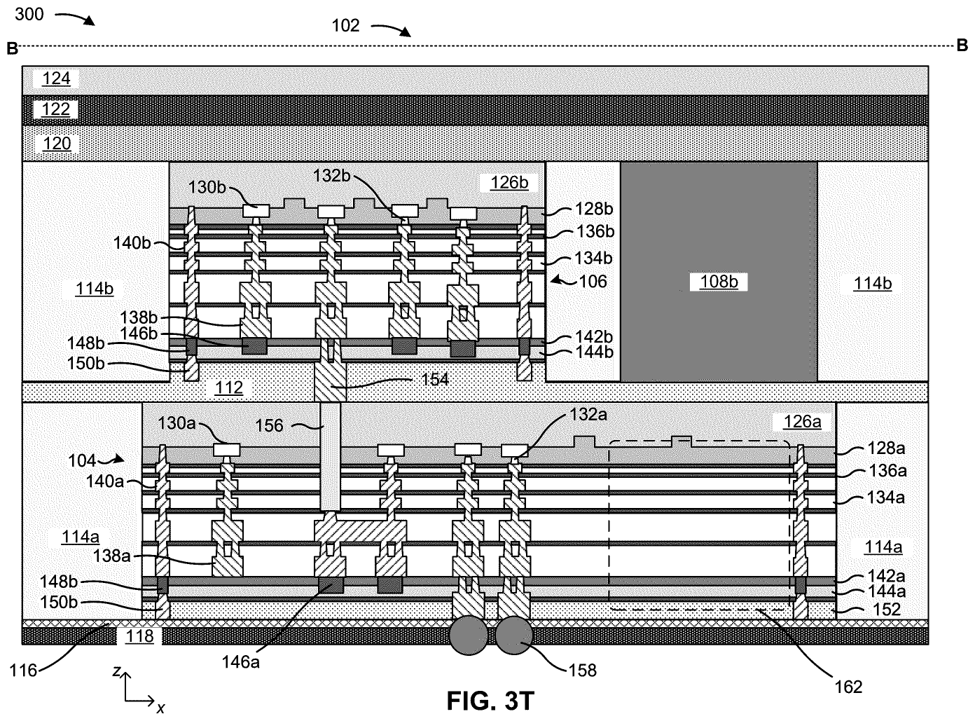

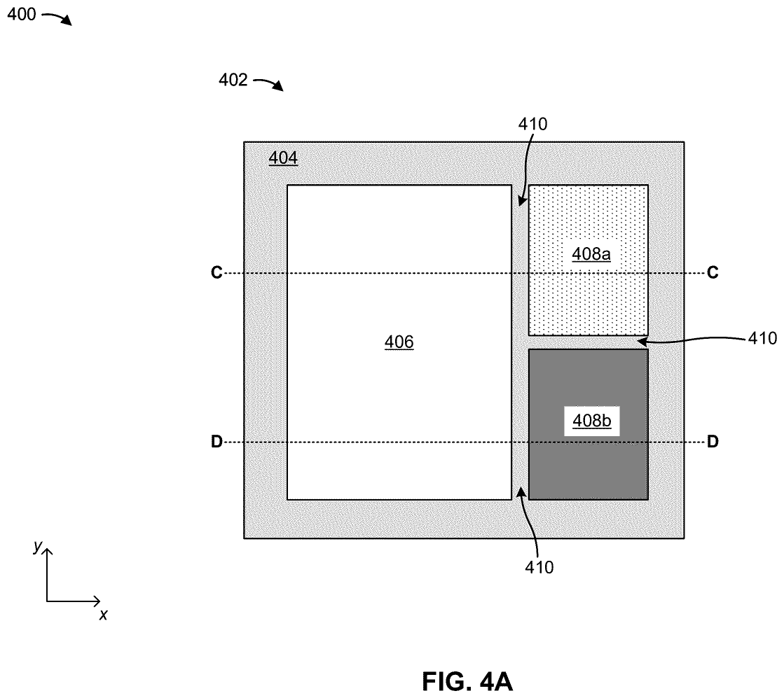

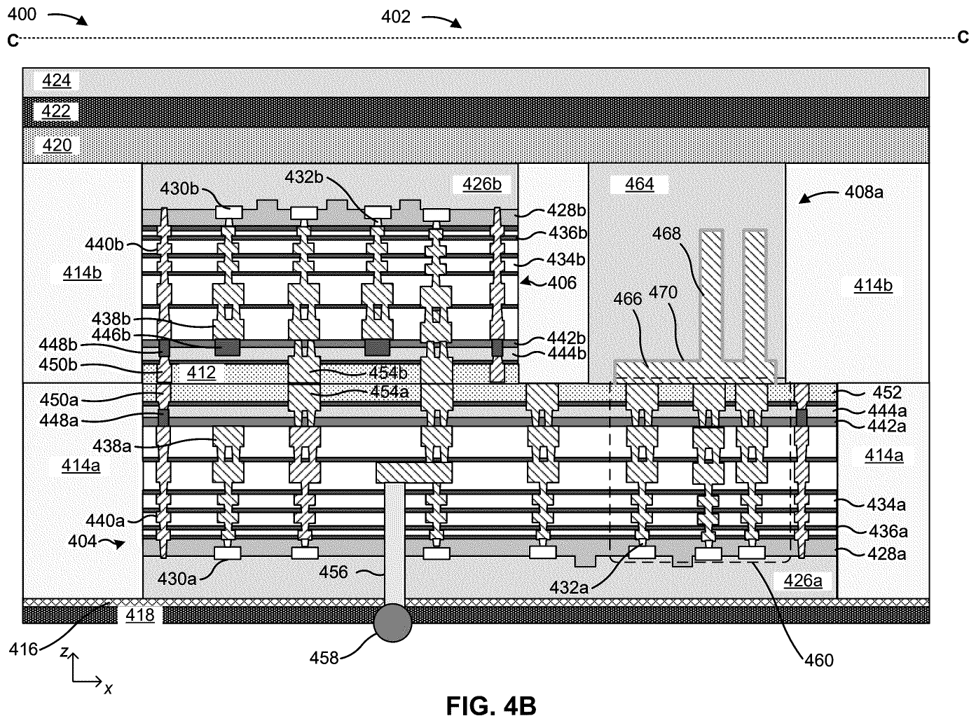

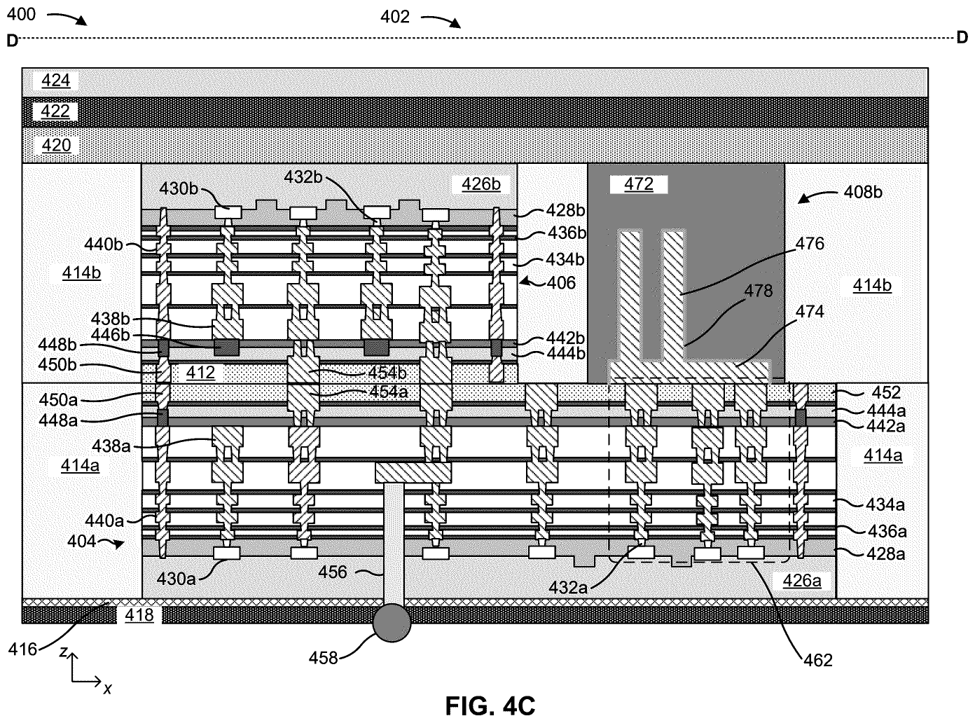

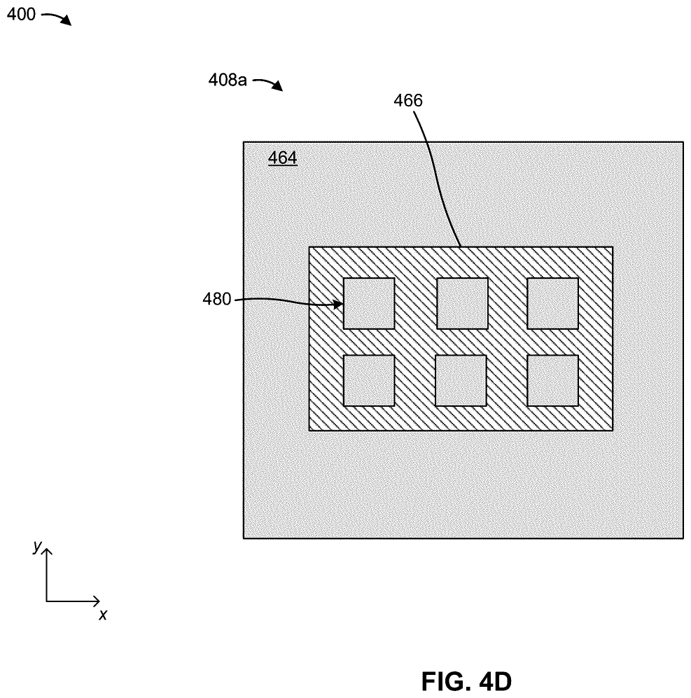

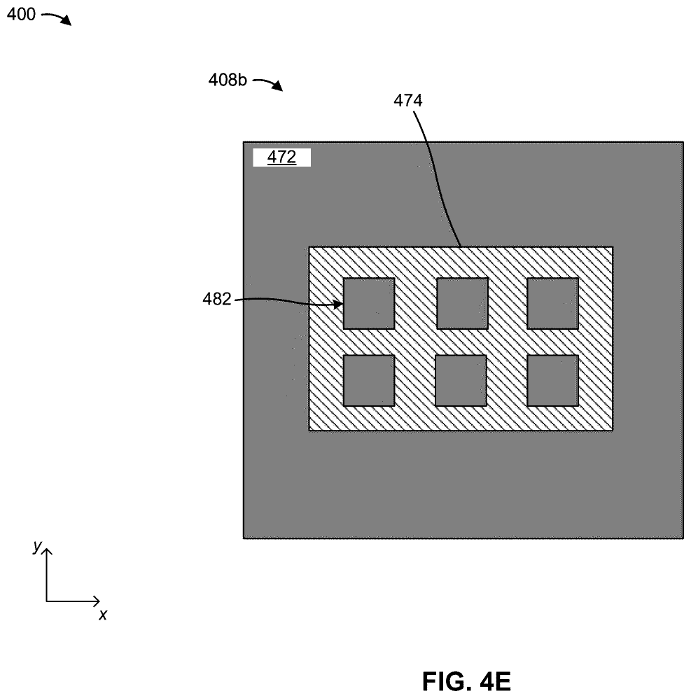

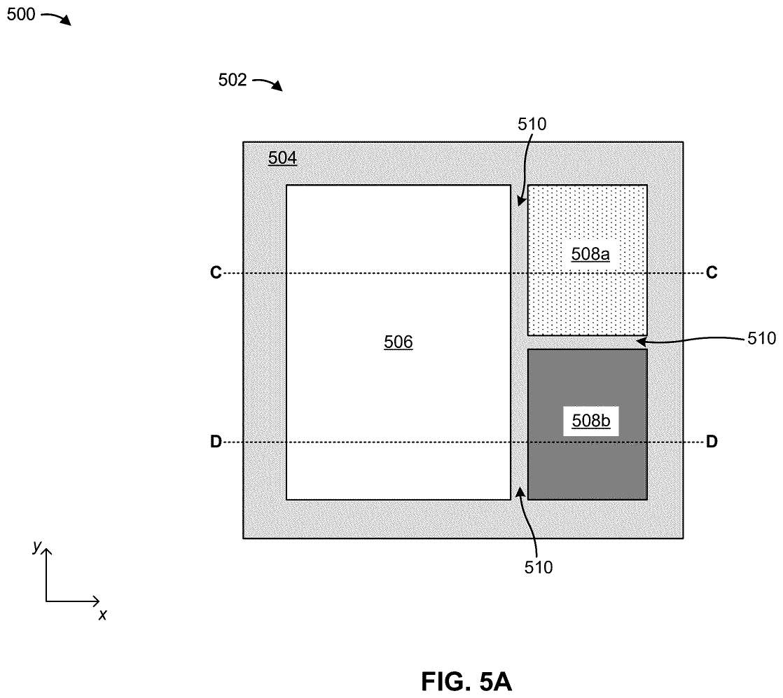

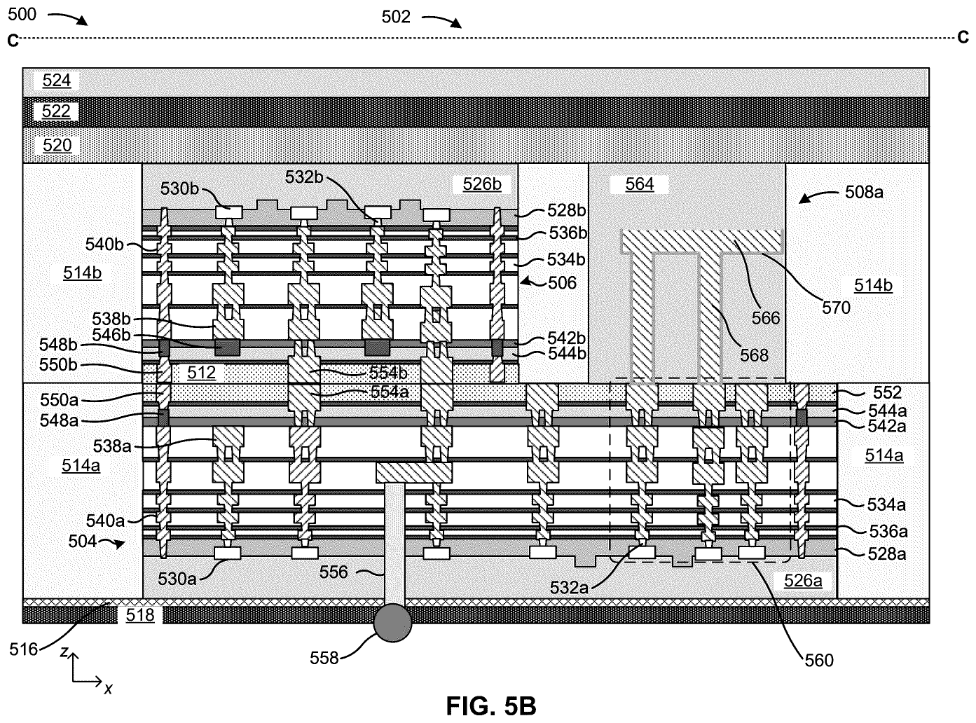

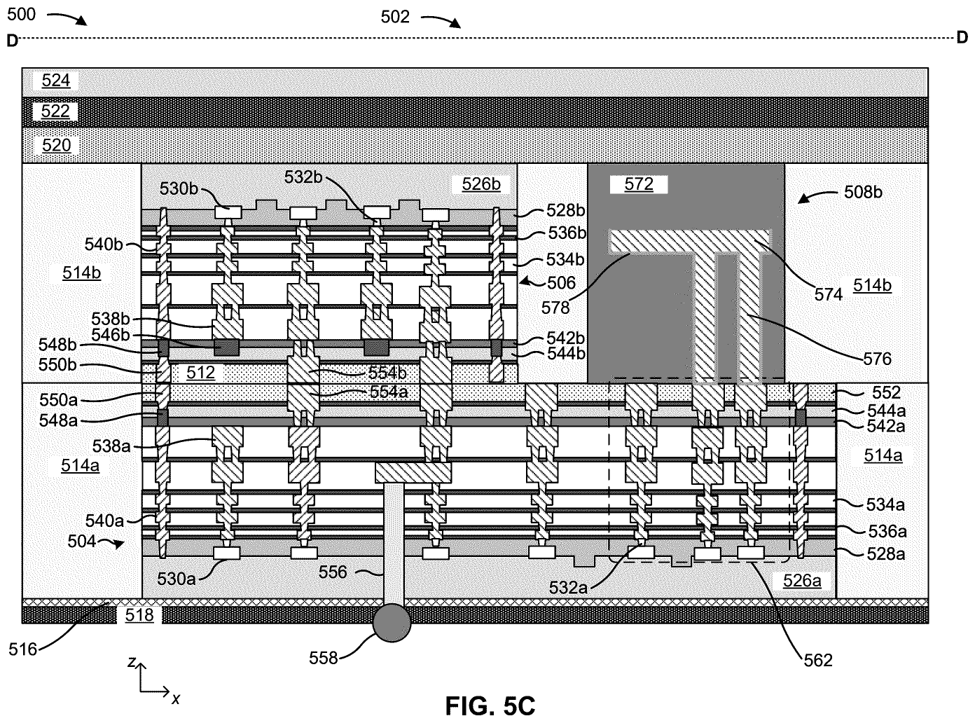

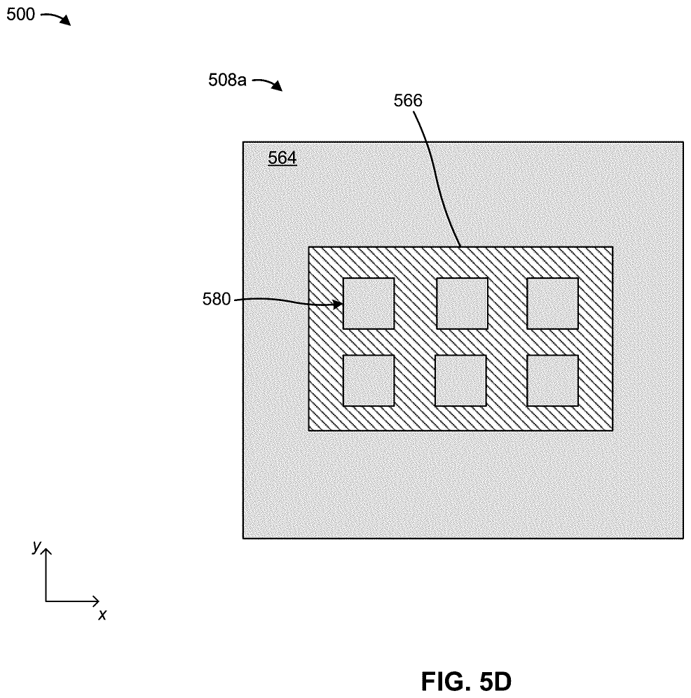

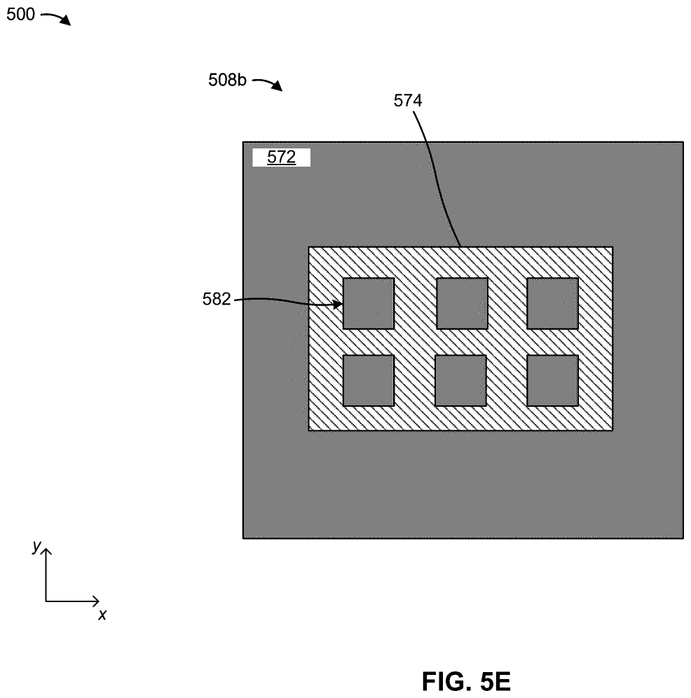

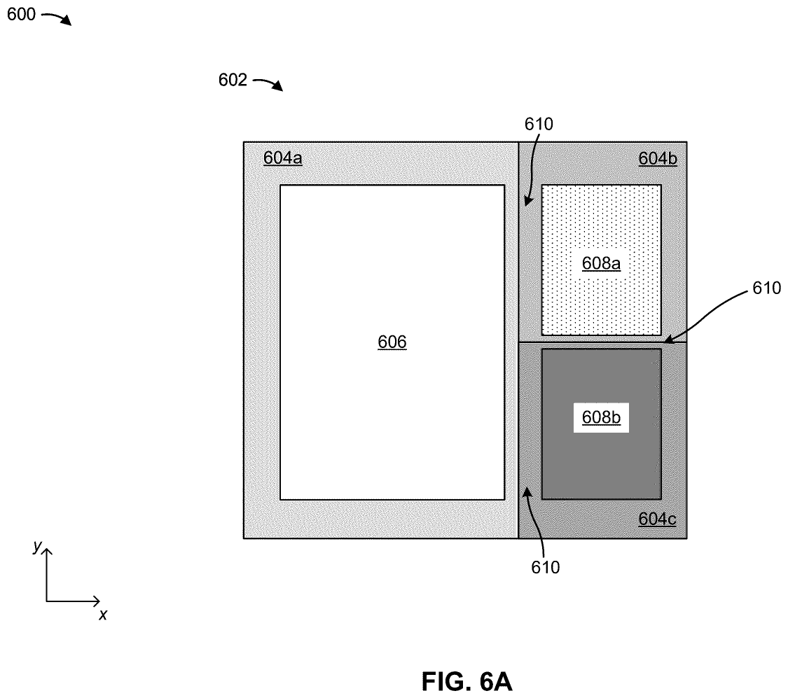

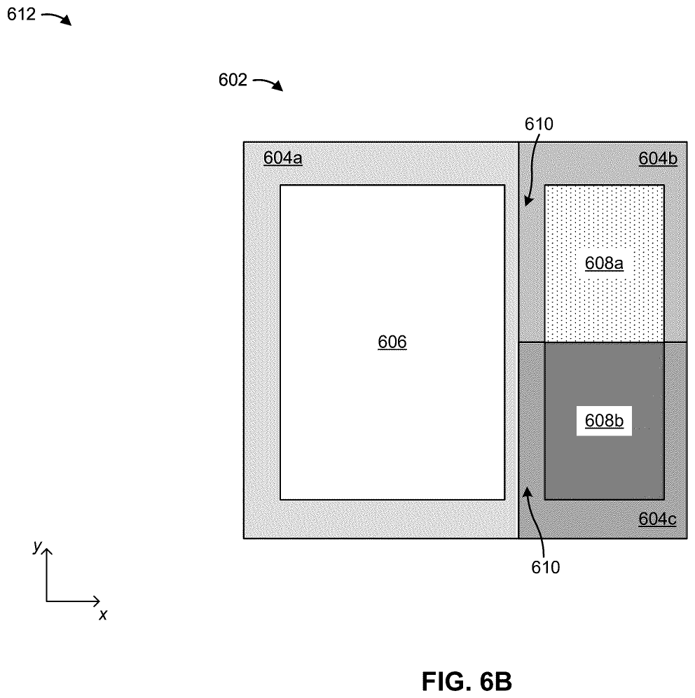

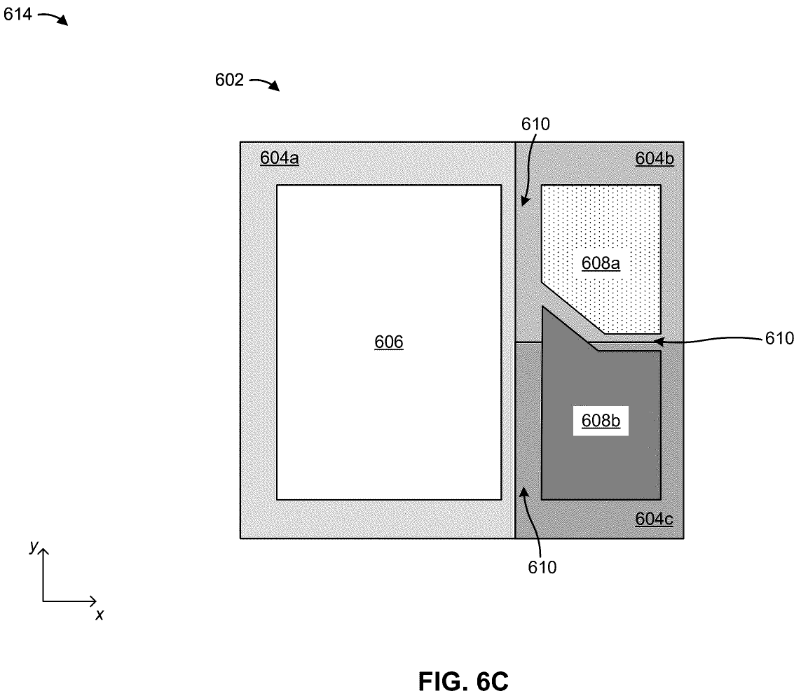

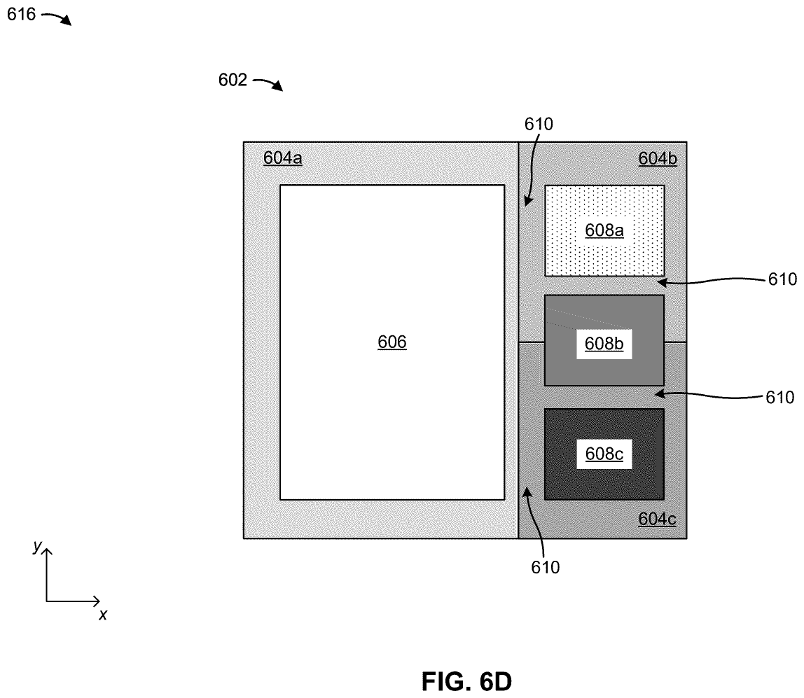

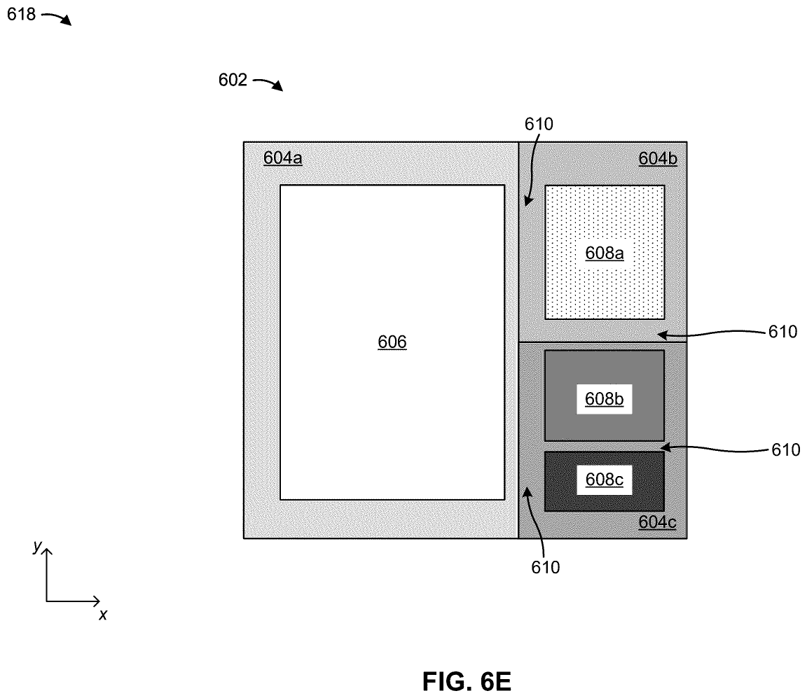

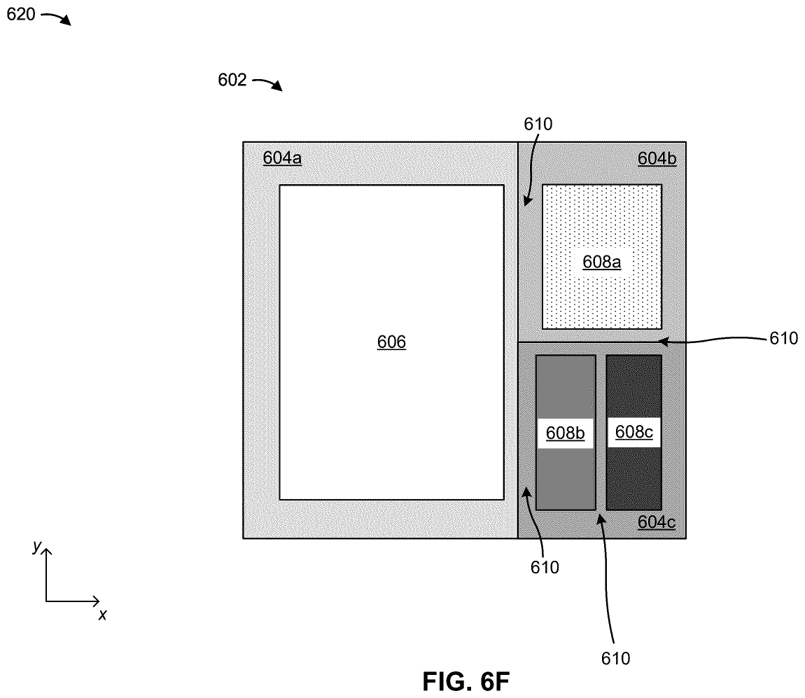

FIGS. 3A-3T are diagrams of an example implementation 300 of forming a semiconductor die package described herein. While the processing operations of the example implementation 300 are illustrated and described in connection with forming the semiconductor die package 102 described herein, the processing operations of the example implementation 300 may be performed to form another semiconductor device described herein, such as a semiconductor die package 402 of FIGS. 4A-4E, a semiconductor die package 502 of FIGS. 5A-5E, and/or a semiconductor die package 602 of FIGS. 6A-6F, among other examples. In some implementations, one or more of the semiconductor processing operations described in connection with FIGS. 3A-3T may be performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

Turning to FIG. 3A, the substrate 126a of the active IC die 104 is provided. The substrate 126a may be provided in the form of a semiconductor wafer such as a silicon (Si) wafer, may be provided as an SOI wafer, and/or another type of semiconductor work piece.

As shown in FIG. 3B, the IC devices 130a may be formed in and/or on the substrate 126a, including in the portion 160 of the active IC die 104 and in the portion 162 (now shown) of the active IC die 104. One or more semiconductor processing tools may be used to form one or more portions of the IC devices 130a. For example, a deposition tool may be used to perform various deposition operations to deposit layers and/or structures of the IC devices 130a, and/or to deposit photoresist layers for etching the substrate 126a and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 126a and/or portions of the deposited layers to form the IC devices 130a. As another example, a planarization tool may be used to planarize portions of the IC devices 130a. As another example, a plating tool may be used to deposit metal structures and/or layers of the IC devices 130a.

As further shown in FIG. 3B, a deposition tool is used to deposit the ILD layer 128a over and/or on the substrate 126a and over and/or on the IC devices 130a. A deposition tool may be used to deposit the ILD layer 128a using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to perform a planarization operation such as a chemical mechanical planarization (CMP) operation to planarize the ILD layer 128a after the ILD layer 128a is deposited.

As shown in FIG. 3C, the contacts 132a of the IC devices 130a may be formed through the ILD layer 128a. The contacts 132a may be formed in recesses in the ILD layer 128a. In some implementations, a pattern in a photoresist layer is used to etch the ILD layer 128a to form the recesses. In these implementations, a deposition tool may be used to form the photoresist layer on the ILD layer 128a. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the ILD layer 128a based on a pattern to form the recesses.

A deposition tool may be used to deposit the material of the contacts 132a in the recesses using a CVD technique, a PVD technique, an ALD technique, an electroplating technique, and/or another suitable deposition technique. The material of the contacts 132a may be deposited in one or more deposition operations. In some implementations, a seed layer is first deposited, and the material of the contacts 132a is deposited on the seed layer. In some implementations, a planarization tool is used to perform a planarization operation (e.g., a CMP operation) to planarize the contacts 132a after the contacts 132a are deposited such that the tops of the contacts 132a are approximately co-planar with the top of the ILD layer 128a.

As shown in FIG. 3C, a first portion of the interconnect layer of the active IC die 104 is formed above the ILD layer 128a. One or more deposition tools are used to deposit alternating layers of ILD layers 134a and ESLs 136a in the first portion of the interconnect layer of the active IC die 104. In this way, the ILD layers 134a and ESLs 136a may be arranged in the z-direction in the active IC die 104. One or more deposition tools may be used to deposit each of the ILD layers 134a and each of the ESLs 136a using a PVD technique, an ALD technique, a CVD technique, an oxidation technique, and/or another suitable deposition technique. In some implementations, a planarization tool may be used to planarize the ILD layers 134a and/or the ESLs 136a after the ILD layers 134a and/or the ESLs 136a are deposited.

As further shown in FIG. 3C, a deposition tool, an exposure tool, a developer tool, an etch tool, a planarization tool, a plating tool, and/or another semiconductor processing tool may be used to perform various operations to form the conductive structures 138a and a first portion of the seal ring structure 140a in the first portion of the interconnect layer of the active IC die 104. The conductive structures 138a and the first portion of the seal ring structure 140a may be included in the ILD layers 134a and/or the ESLs 136a.

The conductive structures 138a and the first portion of the seal ring structure 140a may be formed in recesses in one or more ILD layers 134a and/or in one or more ESLs 136a. In some implementations, a pattern in a photoresist layer is used to etch the ILD layers 134a and ESLs 136a to form the recesses. In these implementations, a deposition tool may be used to form the photoresist layer on the topmost ILD layer 134a. An exposure tool may be used to expose the photoresist layer to a radiation source to pattern the photoresist layer. A developer tool may be used to develop and remove portions of the photoresist layer to expose the pattern. An etch tool may be used to etch the ILD layers 134a and ESLs 136a based on the pattern to form the recesses. In some implementations, the etch operation includes dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the ILD layers 134a and ESLs 136a based on a pattern to form the recesses.

A deposition tool may be used to deposit the material of the conductive structures 138a and the first portion of the seal ring structure 140a in the recesses using a CVD technique, a PVD technique, an ALD technique, an electroplating technique, and/or another suitable deposition technique. The material of the conductive structures 138a and the first portion of the seal ring structure 140a may be deposited in one or more deposition operations. In some implementations, a seed layer is first deposited, and the material of the conductive structures 138a and the first portion of the seal ring structure 140a is deposited on the seed layer. In some implementations, a planarization tool is used to perform a planarization operation (e.g., a CMP operation) to planarize the conductive structures 138a and the first portion of the seal ring structure 140a.

As shown in FIG. 3D, the die-to-die interconnect 156 is formed through the first portion of the interconnect layer and into the substrate 126a. To form the die-to-die interconnect 156, a recess is formed through the first portion of the interconnect layer and into a portion of the substrate 126a. In some implementations, a pattern in a photoresist layer is used to etch the ILD layers 134a and the ESLs 136a of the first portion of the interconnect layer, the ILD layer 128a, and the substrate 126a to form the recess. In these implementations, a deposition tool may be used to form the photoresist layer on the topmost ILD layer 134a. An exposure tool may be used to expose the photoresist layer to a radiation source to pattern the photoresist layer. A developer tool may be used to develop and remove portions of the photoresist layer to expose the pattern. An etch tool may be used to etch the ILD layers 134a and the ESLs 136a of the first portion of the interconnect layer, the ILD layer 128a, and the substrate 126a based on the pattern to form the recess. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess based on a pattern.

A deposition tool may be used to deposit the die-to-die interconnect 156 using a CVD technique, a PVD technique, an ALD technique, an electroplating technique, and/or another suitable deposition technique. The die-to-die interconnect 156 may be deposited in one or more deposition operations. In some implementations, a seed layer is first deposited, and the die-to-die interconnect 156 is deposited on the seed layer. In some implementations, one or more liners (e.g., a barrier liner, an adhesion liner) may first be deposited in the recess, and the die-to-die interconnect 156 may be deposited on the one or more liners in the recess. In some implementations, a planarization tool is used to perform a planarization operation (e.g., a CMP operation) to planarize the die-to-die interconnect 156 after the die-to-die interconnect 156 is deposited.

As shown in FIG. 3E, a second portion of the interconnect layer of the active IC die 104 may be formed. Forming the second portion of the interconnect layer may include forming additional ILD layers 134a, additional ESLs 136a, additional conductive structures 138a, and/or additional portions of the seal ring structure 140a in a similar manner as described in connection with FIG. 3C. As further shown in FIG. 3E, the passivation layer(s) 142a may be deposited, the metal pads 146a may be formed on one or more of the conductive structures 138a, and one or more metal pads 148a may be formed on the seal ring structure 140a.

As shown in FIG. 3F, bonding pads 150a may be formed on the metal pads 148a. In some implementations, bonding pads may also be formed on one or more conductive structures 138a. Moreover, the bonding layer 152 may be formed over the passivation layer(s) 142a, and another bonding layer 302 may be formed on the bonding layer 152. In some implementations, an ESL is deposited on the bonding layer 152, and the bonding layer 302 is deposited on the ESL.

A deposition tool may be used to deposit the bonding pads 150a using a CVD technique, a PVD technique, an ALD technique, an electroplating technique, and/or another suitable deposition technique. The bonding pads 150a may be deposited in one or more deposition operations. In some implementations, a seed layer is first deposited, and the bonding pads 150a are deposited on the seed layer. In some implementations, one or more liners (e.g., a barrier liner, an adhesion liner) may first be deposited in the recess, and the bonding pads 150a may be deposited on the one or more liners in the recess. In some implementations, a planarization tool is used to perform a planarization operation (e.g., a CMP operation) to planarize the bonding pads 150a after the bonding pads 150a are deposited.

A deposition tool may be used to deposit the bonding layers 152 and 302 using a PVD technique, an ALD technique, a CVD technique, an oxidation technique, and/or another suitable deposition technique. The bonding layers 152 and 302 may be deposited in one or more deposition operations. In some implementations, a planarization tool may be used to perform a planarization operation (e.g., a CMP operation) to planarize the bonding layers 152 and 302 after the bonding layers 152 and 302 are deposited.

As shown in FIG. 3G, the active IC die 104 is bonded to a carrier substrate 304 using the bonding layers 302 and 306. Accordingly, the active IC die 104 may be flipped or rotated 180 degrees to bond the active IC die 104 to the carrier substrate 304. Moreover, a bonding layer 306 (e.g., a fusion bonding layer or another type of bonding layer) included on the carrier substrate 304 is used to bond the active IC die 104 and the carrier substrate 304. A bonding tool may be used to bond the active IC die 104 to the carrier substrate 304 using a fusion bonding technique and/or another bonding technique.

As shown in FIG. 3H, areas around the active IC die 104 are filled with the dielectric fill layer 114a. A deposition tool may be used to deposit the dielectric fill layer 114a using a PVD technique, an ALD technique, a CVD technique, an oxidation technique, and/or another suitable deposition technique. The dielectric fill layer 114a may be deposited in one or more deposition operations.

As further shown in FIG. 3H, a planarization tool or wafer grinding tool may be used to perform a planarization operation (e.g., a CMP operation, a wafer grinding operation) to planarize the dielectric fill layer 114a and to remove material from the back side of the substrate 126a such that the die-to-die interconnect 156 is exposed through the back side of the substrate 126a.

As shown in FIG. 31, the bonding layer 112 is formed over and/or on the back side of the substrate 126a of the active IC die 104. A deposition tool may be used to deposit the bonding layer 112 using a PVD technique, an ALD technique, a CVD technique, an oxidation technique, and/or another suitable deposition technique. In some implementations, planarization tool is used to perform a planarization operation (e.g., a CMP operation,) to planarize the bonding layer 112.

As shown in FIGS. 3J and 3K, the active IC die 106 is bonded to the active IC die 104 such that the active IC die 104 and the active IC die 106 are stacked and vertically arranged in the semiconductor die package 102. The active IC die 106 may be formed using similar techniques and processes as those described in connection with FIGS. 3A-3I.

In some implementations, a bonding tool is used to bond the active IC die 104 and the active IC die 106 by forming dielectric-to-dielectric bonds between bonding layers 112 on each of the active IC die 104 and the active IC die 106. In some implementations, a bonding tool is used to bond the active IC die 104 and the active IC die 106 by forming metal-to-metal bonds between the die-to-die interconnect 156 of the active IC die 104 and the bonding pads 154 of the active IC die 106. In some implementations, a bonding tool is used to bond the active IC die 104 and the active IC die 106 by forming a combination of dielectric-to-dielectric bonds and metal-to-metal bonds.

As shown in FIG. 3L, the non-active dies 108a and 108b may be provided over and/or on the active IC die 104 such that the non-active dies 108a and 108b are laterally adjacent to one or more sides of the active IC die 106. In particular, the non-active dies 108a and 108b may be provided over and/or on the same side of the active IC die 104 to which the active IC die 104 is bonded. As shown in FIG. 3M, the non-active die 108a may be provided over the portion 160 of the active IC die 104. As shown in FIG. 3N, the non-active die 108b may be provided over the portion 162 of the active IC die 104. The non-active dies 108a and 108b may be arranged in one or more of the configurations illustrated and described herein, such as in connection with FIGS. 1A-1C, 2A-2I, 4A-4E, 5A-5E, and/or 6A-6F, among other examples. In some implementations, a non-active die 108c is also provided over and/or on the active IC die 104. In some implementations, the non-active dies 108a and 108b (and, in some implementations, the non-active die 108c and/or additional non-active dies) are arranged in another configuration.

In some implementations, the non-active dies 108a and/or 108b include semiconductor dies (e.g., silicon dies), and the non-active dies 108a and/or 108b are bonded to the bonding layer 112. In some implementations, the non-active dies 108a and/or 108b include dielectric layers (e.g., dielectric thick films) that are deposited onto the active IC die 104 using a deposition tool. In these implementations, the non-active dies 108a and/or 108b may be deposited using a CVD technique, a PVD technique, an ALD technique, an oxidation technique, and/or another suitable deposition technique.

As shown in FIGS. 3O and 3P, areas around the active IC die 106, areas around the non-active die 108a, and areas around the non-active die 108b are filled with the dielectric fill layer 114b. If the active IC die 106, the non-active die 108a, and/or the non-active die 108b are spaced apart by gaps 110, the gaps 110 may be filled in with material of the dielectric fill layer 114b. A deposition tool may be used to deposit the dielectric fill layer 114b using a PVD technique, an ALD technique, a CVD technique, an oxidation technique, and/or another suitable deposition technique. The dielectric fill layer 114b may be deposited in one or more deposition operations. A planarization tool may be used to perform a planarization operation (e.g., a CMP operation) to planarize the dielectric fill layer 114b, the substrate 126b of the active IC die 106, and the non-active dies 108a and 108b such that the dielectric fill layer 114b, the substrate 126b of the active IC die 106, and the non-active dies 108a and 108b are approximately co-planar.

As shown in FIG. 3Q, the semiconductor die package 102 the passivation layers 120-124 are formed or provided above the active IC die 106. A deposition tool may be used to deposit the passivation layers 120-124 using a PVD technique, an ALD technique, a CVD technique, an oxidation technique, and/or another suitable deposition technique. The passivation layers 120-124 may be deposited in one or more deposition operations. In some implementations, a planarization tool may be used to perform a planarization operation (e.g., a CMP operation) to planarize the passivation layers 120-124 after the passivation layers 120-124 are deposited. Additionally and/or alternatively, one or more of the passivation layers 120-124 may be dispensed onto the active IC die 104. Additionally and/or alternatively, the semiconductor die package 102 may be placed over and/or on one or more of the passivation layers 120-124 on a carrier substrate.

As shown in FIG. 3R, the semiconductor die package 102 is flipped and one or more operations are performed to remove the carrier substrate 304 and the bonding layers 302 and 306 from the semiconductor die package 102. In some implementations, the carrier substrate 304 is de-bonded from the semiconductor die package 102 by a thermal operation to alter the adhesive properties of the bonding layers 302 and/or 306. An energy source such as an ultraviolet (UV) laser, a carbon dioxide (CO₂) laser, or an infrared (IR) laser, among other examples, is utilized to irradiate and heat the bonding layers 302 and/or 306 until the adhesive properties of the bonding layer 302 and/or 306 are reduced. Then, the carrier substrate 304 and the bonding layers 302 and 306 are physically separated and removed from the semiconductor die package 102. Additionally and/or alternatively, the carrier substrate 304, the bonding layer 302, and/or the bonding layer 306 may be removed by etching and/or planarization.

As shown in FIGS. 3S and 3T, the passivation layers 116 and 118 are formed on the active IC die 104. A deposition tool may be used to deposit the passivation layers 116 and 118 using a PVD technique, an ALD technique, a CVD technique, an oxidation technique, and/or another suitable deposition technique. The passivation layers 116 and 118 may be deposited in one or more deposition operations. In some implementations, a planarization tool may be used to perform a planarization operation (e.g., a CMP operation) to planarize the passivation layers 116 and 118 after the passivation layers 116 and 118 are deposited. Additionally and/or alternatively, passivation layers 116 and/or 118 may be dispensed onto the active IC die 104. The connection structures 158 may also be attached to the semiconductor die package 102.

As indicated above, FIGS. 3A-3T are provided as an example. Other examples may differ from what is described with regard to FIGS. 3A-3T.

FIGS. 4A-4E are diagrams of an example 400 of a semiconductor die package 402 described herein. The semiconductor die package 402 includes a packaged semiconductor device that includes a plurality of active IC dies or chips. The plurality of active IC dies may be vertically arranged and/or stacked in the semiconductor die package 402 using 3D packaging techniques such as direct bonding. FIG. 4A illustrates a top view of the semiconductor die package 402. FIG. 4B illustrates a cross-section view of the semiconductor die package 402 along the line C-C in FIG. 4A. FIG. 4C illustrates a cross-section view of the semiconductor die package 402 along the line D-D in FIG. 4A.

As shown in FIGS. 4A-4C, the semiconductor die package 402 includes a similar combination and arrangement of layers and/or structures 404-462 as the layers and/or structures 104-162 of the semiconductor die package 102 illustrated and described in connection with FIGS. 1A-1C. The layers and/or structures 404-462 of the semiconductor die package 402 may be formed using similar techniques and/or processes to those described in connection with FIGS. 3A-3T.

However, as shown in FIGS. 4B and 4C, the active IC dies 404 and 406 or oriented in a mirrored configuration such that the interconnect layers of the active IC dies 404 and 406 are facing each other. This enables the active IC dies 404 and 406 to be directly bonded in a dielectric-to-dielectric bond between bonding layers 412 and 452 respectively of the active IC dies 404 and 406, and in metal-to-metal bonds between bonding pads 454a and 454b respectively of the active IC dies 404 and 406.

As further shown in FIG. 4B, the non-active die 408a further includes a semiconductor structure 464 (e.g., a semiconductor die such as a silicon (Si) die) and conductive structures in the semiconductor structure 464, including a trench structure 466 and one or more via structures 468. The non-active die 408a may be manufactured from a semiconductor wafer that is processes to form the trench structure 466 and via structure(s) 468 in the semiconductor structure 464 (which may correspond to a portion of the semiconductor wafer).

The trench structure 466 and the via structure(s) 468 may be included to increase the structural rigidity of the non-active die 408a, which provides increased structural rigidity for the semiconductor die package 402. Additionally and/or alternatively, the trench structure 466 and the via structure(s) 468 may be included to provide a thermal conduction path for heat generated in the portion 460 of the active IC die 404. Additionally and/or alternatively, the orientation of active IC dies 404 and 406, in combination with the trench structure 466 in the non-active die 408a, enable metal-to-metal bonds to be formed between the trench structure 466 and bonding pads 454a in the active IC die 404, which enables the non-active die 408a and the active IC die 404 to be directly bonded.

The trench structure 466 and the via structure(s) 468 may each include tungsten (W), cobalt (Co), ruthenium (Ru), titanium (Ti), aluminum (Al), and/or gold (Au), among other electrically conductive materials. In the non-active die 408a, the via structure(s) 468 may be located adjacent to a side of the non-active die 408a that is facing away from the active IC die 406. In some implementations, one or more liners 470 are included between the semiconductor structure 464 of the non-active die 408a and the trench structure 466 and the via structure(s) 468. The one or more liners 470 may include a tantalum nitride (TaN) barrier layer, a titanium (Ti) or titanium nitride (TiN) barrier layer, a silicon oxide (SiOₓ such as SiO₂) liner and/or another suitable liner.

As further shown in FIG. 4C, the non-active die 408b further includes a dielectric structure 472 (e.g., a silicon oxide (SiOₓ) thick film or another type of dielectric thick film) and conductive structures in the dielectric structure 472, including a trench structure 474 and one or more via structures 476. The non-active die 408b may be manufactured over and/or on the active IC die 404 by depositing the dielectric structure 472 onto the active IC die 404 and then forming the trench structure 474 and via structure(s) 476 in the dielectric structure 472.

The trench structure 474 and the via structure(s) 476 may be included to increase the structural rigidity of the non-active die 408b, which provides increased structural rigidity for the semiconductor die package 402. Additionally and/or alternatively, the trench structure 474 and the via structure(s) 476 may be included to provide a thermal conduction path for heat generated in the portion 462 of the active IC die 404. Additionally and/or alternatively, the orientation of active IC dies 404 and 406, in combination with the trench structure 474 in the non-active die 408b, enable metal-to-metal bonds to be formed between the trench structure 474 and bonding pads 454a in the active IC die 404, which enables the non-active die 408a and the active IC die 404 to be directly bonded.

The trench structure 474 and the via structure(s) 476 may each include tungsten (W), cobalt (Co), ruthenium (Ru), titanium (Ti), aluminum (Al), and/or gold (Au), among other electrically conductive materials. In the non-active die 408b, the via structure(s) 476 may be located adjacent to a side of the non-active die 408a that is facing the active IC die 406. In some implementations, one or more liners 478 are included between the dielectric structure 472 of the non-active die 408b and the trench structure 474 and the via structure(s) 476. The one or more liners 478 may include a tantalum nitride (TaN) barrier layer, a titanium (Ti) or titanium nitride (TiN) barrier layer, a silicon oxide (SiOₓ such as SiO₂) liner and/or another suitable liner.

FIG. 4D illustrates a bottom view of the trench structure 466 included in the non-active die 408a. As shown in FIG. 4D, the trench structure 466 may include a plurality of intersecting trenches that are arranged in a grid. This forms a mesh pattern having openings 480 that are formed between the intersecting trenches of the trench structure 466. The grid arrangement of the trench structure 466 may reduce the likelihood of dishing in the semiconductor structure 464 when planarizing the trench structure 466. In some implementations, an overall x-direction width of the trench structure 466 may be included in a range of approximately 3 microns to 7 microns. However, other values for the range are within the scope of the present disclosure. In some implementations, an overall y-direction width of the trench structure 466 may be included in a range of approximately 3 microns to 7 microns. However, other values for the range are within the scope of the present disclosure.

FIG. 4E illustrates a bottom view of the trench structure 474 included in the non-active die 408b. As shown in FIG. 4E, the trench structure 474 may include a plurality of intersecting trenches that are arranged in a grid. This forms a mesh pattern having openings 482 that are formed between the intersecting trenches of the trench structure 474. The grid arrangement of the trench structure 474 may reduce the likelihood of dishing in the dielectric structure 472 when planarizing the trench structure 474. In some implementations, an overall x-direction width of the trench structure 474 may be included in a range of approximately 3 microns to 7 microns. However, other values for the range are within the scope of the present disclosure. In some implementations, an overall y-direction width of the trench structure 474 may be included in a range of approximately 3 microns to 7 microns. However, other values for the range are within the scope of the present disclosure.

As indicated above, FIGS. 4A-4E are provided as examples. Other examples may differ from what is described with regard to FIGS. 4A-4E.

FIGS. 5A-5E are diagrams of an example 500 of a semiconductor die package 502 described herein. The semiconductor die package 502 includes a packaged semiconductor device that includes a plurality of active IC dies or chips. The plurality of active IC dies may be vertically arranged and/or stacked in the semiconductor die package 502 using 3D packaging techniques such as direct bonding.

As shown in FIGS. 5A-5E, the semiconductor die package 502 includes a similar combination and arrangement of layers and/or structures 504-582 as the layers and/or structures 404-482 of the semiconductor die package 402 illustrated and described in connection with FIGS. 4A-4E. The layers and/or structures 504-582 of the semiconductor die package 502 may be formed using similar techniques and/or processes to those described in connection with FIGS. 3A-3T.

However, as shown in FIG. 5B, the vertical (z-direction) orientation of the trench structure 566 and the via structure(s) 568 is reversed such that the via structure(s) 568 are bonded to the bonding pads 554a in the active IC die 504. Similarly, as shown in FIG. 5C, the vertical (z-direction) orientation of the trench structure 574 and the via structure(s) 576 is reversed such that the via structure(s) 576 are bonded to the bonding pads 554a in the active IC die 504.

As indicated above, FIGS. 5A-5E are provided as examples. Other examples may differ from what is described with regard to FIGS. 5A-5E.

FIGS. 6A-6F are diagrams of examples of top view layouts for a semiconductor die package described herein. FIG. 6A illustrates an example 600 of a top view layout for a semiconductor die package 602. As shown in FIG. 6A, the semiconductor die package 602 includes a similar combination and arrangement of dies in the example 600 as the semiconductor die package 102 in FIG. 1A. However, the semiconductor die package 602 includes a plurality of active IC dies 604a-604c that may be laterally adjacent to each other in the semiconductor die package 602. An active IC die 606 may be included over and/or on and vertically arranged with the active IC die 604a. A non-active die 608a may be included over and/or on and vertically arranged with the active IC die 604b, and a non-active die 608b may be included over and/or on and vertically arranged with the active IC die 604c. In other words, the active IC die 606 and the non-active dies 608a and 608b are each included over and/or on a different active IC die. In the example 600, the active IC die 606 and the non-active die 608a are spaced apart by a gap 610, the active IC die 606 and the non-active die 608b are spaced apart by a gap 610, and the non-active dies 608a and 608b are spaced apart by a gap 610.

Including the non-active dies 608a and 608b over and/or on different active IC dies enables the non-active dies 608a and 608b to be manufactured to optimize the non-active dies 608a and 608b for the attributes of the active IC dies 604b and 604c, respectively. The non-active dies 608a and 608b may include different materials (or different material compositions), have different structural arrangements of layers and/or features, may include different combinations and arrangements of devices, and/or may have different top view sizes and/or shapes, among other examples. For example, active IC die 604b may include a logic die and the active IC die 604c may include a silicon photonics die. Thus, the non-active die 608a may include a semiconductor non-active die that provides a high amount of thermal conductivity to dissipate heat from the logic devices in the logic die, whereas the non-active die 608a may include a dielectric film that provides a low amount of thermal conductivity to maintain high operating temperatures in the silicon photonics die (e.g., that includes silicon photonics devices such as optical modulators that have more stable operation at higher temperatures).

The active IC dies 604-604c and 606 may each include a similar combination and arrangement of layers and/or structures as those illustrated for one or more of the active IC dies in FIGS. 1B, 1C, 4B, 4C, 5B, and/or 5C, among other examples. Additionally and/or alternatively, the non-active dies 608a and 608b may each include a similar combination and arrangement of layers and/or structures as those illustrated for one or more of the non-active dies in FIGS. 1B, 1C, 4B, 4C, 4D, 4E, 5B, 5C, 5D, and/or 5E, among other examples. The layers the semiconductor die package 602 may be formed using similar techniques and/or processes to those described in connection with FIGS. 3A-3T.

As shown in FIG. 6B, an example 612 of a top view layout for non-active devices in the semiconductor die package 602 includes a similar top view layout as illustrated in FIG. 6A, except that the non-active dies 608a and 608b are in physical contact along adjacent edges that are approximately orthogonal to the edges of non-active dies 608a and 608b that are adjacent to the active IC die 606.

As shown in FIG. 6C, an example 614 of a top view layout for non-active dies in the semiconductor die package 602 includes a similar top view layout as illustrated in FIG. 6A, except that the non-active dies 608a and 608b have different top view sizes. The non-active dies 608a and 608b may have different top view sizes such that the non-active die 608b, for example, may also be located over a portion of the active IC die 604b. Thus, the non-active die 608b may be configured to optimize the thermal and/or structural performance of a portion of the active IC die 604b, in addition to be configured to optimize the thermal and/or structural performance for the active IC die 604c.

As shown in FIG. 6D, an example 616 of a top view layout for non-active dies in a semiconductor die package 602 includes a similar top view layout as illustrated in FIG. 6A, except that another non-active die 608c is included over and/or on the active IC die 604c. The non-active die 608b spans across portions of the active IC dies 604b and 604c, and is included above the portions of the active IC dies 604b and 604c. Other quantities of non-active dies are also within the scope of the present disclosure. Increasing the quantity of non-active dies, such as in the example 616 in FIG. 6D, enables increased flexibility in tuning the non-active dies for different portions or regions of the active IC dies 604b and 604c, thereby increasing the thermal management performance and/or structural integrity of the semiconductor die package 602.

As shown in FIG. 6E, an example 618 of a top view layout for non-active dies in a semiconductor die package 602 includes a similar top view layout as illustrated in FIG. 6D, except that two or more of the non-active dies 608a-608c have different top view sizes and are fully contained within the perimeter of the same active IC die. For example, the non-active dies 608b and 608c may both be fully contained within the perimeter of the same active IC die 604c. This enables increased flexibility in tuning the non-active dies 608b and 608c for different portions or regions of the active IC die 604c.

As shown in FIG. 6F, an example 620 of a top view layout for non-active dies in a semiconductor die package 602 includes a similar top view layout as illustrated in FIG. 6E, except that the non-active dies 608b and 608c are arranged in the x-direction as opposed to the non-active dies 608a-608c all being arranged in the y-direction in the example 618 in FIG. 6E. Other combinations of x-direction arrangement and/or y-direction arrangement are within the scope of the present disclosure, and enable increased flexibility in tuning the non-active dies for different portions or regions of the active IC dies 604b and/or 604c, thereby increasing the thermal management performance and/or structural integrity of the semiconductor die package 602.

As indicated above, FIGS. 6A-6F are provided as examples. Other examples may differ from what is described with regard to FIGS. 6A-6F.

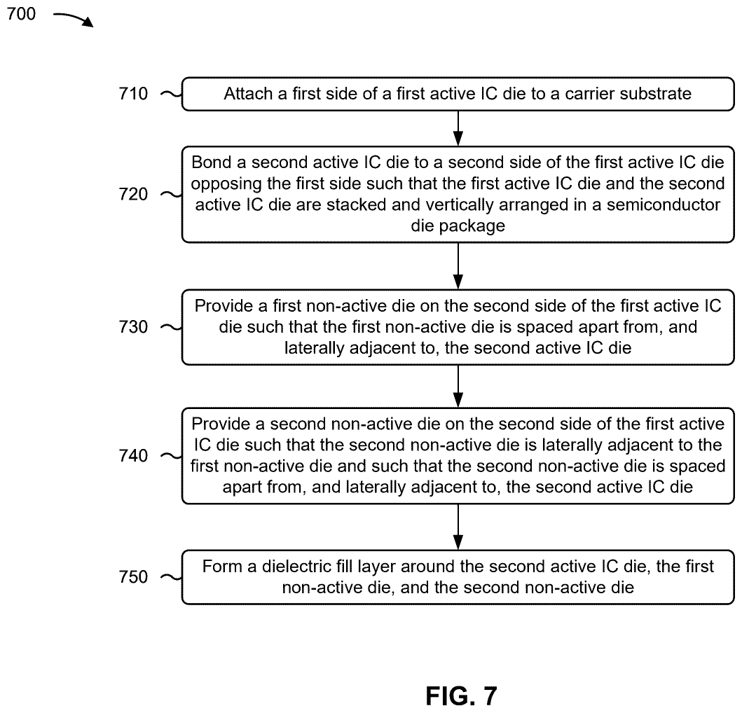

FIG. 7 is a flowchart of an example process 700 associated with forming a semiconductor die package described herein. In some implementations, one or more process blocks of FIG. 7 are performed using one or more semiconductor processing tools, such as a deposition tool, an exposure tool, a developer tool, an etch tool, a planarization tool, an ion implantation tool, an annealing tool, a bonding tool, a wafer/die transport tool, and/or another type of semiconductor processing tool.

As shown in FIG. 7, process 700 may include attaching a first side of a first active IC die to a carrier substrate (block 710). For example, one or more semiconductor processing tools may be used to attach a first side of a first active IC die (e.g., an active IC die 104, an active IC die 404, an active IC die 504) to a carrier substrate (e.g., a carrier substrate 304), as described herein.

As further shown in FIG. 7, process 700 may include bonding a second active IC die to a second side of the first active IC die opposing the first side such that the first active IC die and the second active IC die are stacked and vertically arranged in a semiconductor die package (block 720). For example, one or more semiconductor processing tools may be used to bond a second active IC die (e.g., an active IC die 106, an active IC die 406, an active IC die 506) to a second side of the first active IC die opposing the first side such that the first active IC die and the second active IC die are stacked and vertically arranged in a semiconductor die package (e.g., a semiconductor die package 102, a semiconductor die package 402, a semiconductor die package 502), as described herein.

As further shown in FIG. 7, process 700 may include providing a first non-active die on the second side of the first active IC die such that the first non-active die is spaced apart from, and laterally adjacent to, the second active IC die (block 730). For example, one or more semiconductor processing tools may be used to provide a first non-active die (e.g., a non-active die 108a, a non-active die 408a, a non-active die 508a) on the second side of the first active IC die such that the first non-active die is spaced apart from, and laterally adjacent to, the second active IC die, as described herein.

As further shown in FIG. 7, process 700 may include providing a second non-active die on the second side of the first active IC die such that the second non-active die is laterally adjacent to the first non-active die and such that the second non-active die is spaced apart from, and laterally adjacent to, the second active IC die (block 740). For example, one or more semiconductor processing tools may be used to provide a second non-active die (e.g., a non-active die 108b, a non-active die 108c, a non-active die 408b, a non-active die 508b) on the second side of the first active IC die such that the second non-active die is laterally adjacent to the first non-active die and such that the second non-active die is spaced apart from, and laterally adjacent to, the second active IC die, as described herein.

As further shown in FIG. 7, process 700 may include forming a dielectric fill layer around the second active IC die, the first non-active die, and the second non-active die (block 750). For example, one or more semiconductor processing tools may be used to form a dielectric fill layer (e.g., a dielectric fill layer 114b, a dielectric fill layer 414b, a dielectric fill layer 514b) around the second active IC die, the first non-active die, and the second non-active die, as described herein.

Process 700 may include additional implementations, such as any single implementation or any combination of implementations described below and/or in connection with one or more other processes described elsewhere herein.

In a first implementation, providing the first non-active die on the second side of the first active IC die includes placing the non-active die on the second side of the first active IC die.

In a second implementation, alone or in combination with the first implementation, providing the second non-active die on the second side of the first active IC die includes depositing the non-active die as a film on the second side of the first active IC die.

In a third implementation, alone or in combination with one or more of the first and second implementations, providing the first non-active die on the second side of the first active IC die includes bonding a conductive trench structure (e.g., a conductive trench structure 466) in the first non-active die to a bonding pad (e.g., a bonding pad 554a) in the first active IC die.

In a fourth implementation, alone or in combination with one or more of the first through third implementations, the conductive trench structure includes a plurality of interconnected conductive trenches arranged in a grid.

In a fifth implementation, alone or in combination with one or more of the first through fourth implementations, providing the first non-active die on the second side of the first active IC die comprises bonding a conductive via structure (e.g., a conductive via structure 568) in the first non-active die with a bonding pad (e.g., a bonding pad 554a) in the first active IC die.

In a sixth implementation, alone or in combination with one or more of the first through fifth implementations, process 700 includes forming the conductive via structure in at least one of a semiconductor layer or a dielectric layer of the first non-active die, and forming a conductive trench structure (e.g., a conductive trench structure 566) such that the conductive trench structure is coupled to the conductive via structure.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

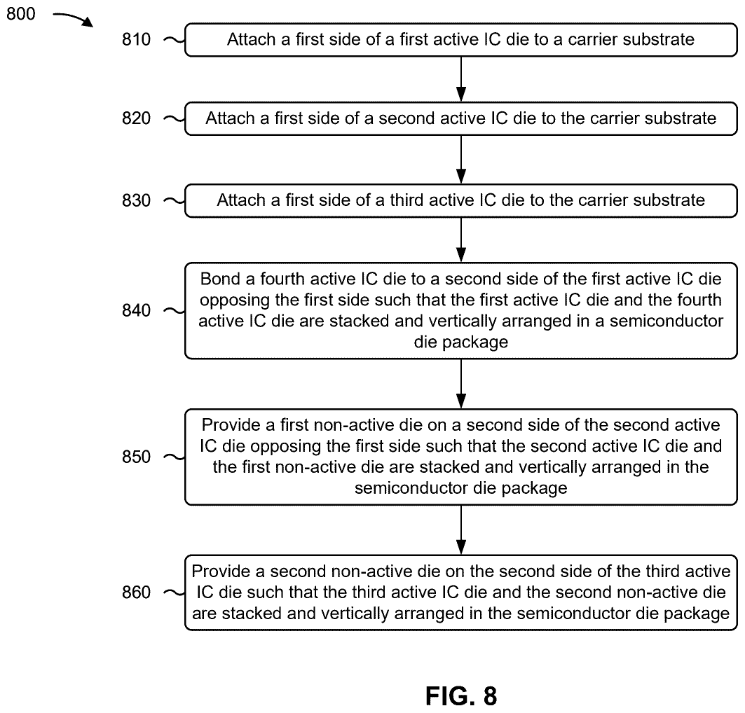

FIG. 8 is a flowchart of an example process 800 associated with forming a semiconductor die package described herein. In some implementations, one or more process blocks of FIG. 8 are performed using one or more semiconductor processing tools, such as a deposition tool, an exposure tool, a developer tool, an etch tool, a planarization tool, an ion implantation tool, an annealing tool, a bonding tool, a wafer/die transport tool, and/or another type of semiconductor processing tool.

As shown in FIG. 8, process 800 may include attaching a first side of a first active IC die to a carrier substrate (block 810). For example, one or more semiconductor processing tools may be used to attach a first side of a first active IC die (e.g., an active IC die 604a) to a carrier substrate (e.g., a carrier substrate 304), as described herein.

As shown in FIG. 8, process 800 may include attaching a first side of a second active IC die to the carrier substrate (block 820). For example, one or more semiconductor processing tools may be used to attach a first side of a second active IC die (e.g., an active IC die 604b) to the carrier substrate, as described herein. In some implementations, the first active IC die and the second active IC die are laterally adjacent on the carrier substrate.

As shown in FIG. 8, process 800 may include attaching a first side of a third active IC die to the carrier substrate (block 830). For example, one or more semiconductor processing tools may be used to attach a first side of a third active IC die (e.g., an active IC die 604c) to the carrier substrate, as described herein. In some implementations, the first active IC die and the third active IC die are laterally adjacent on the carrier substrate.

As further shown in FIG. 8, process 800 may include bonding a fourth active IC die to a second side of the first active IC die opposing the first side such that the first active IC die and the fourth active IC die are stacked and vertically arranged in a semiconductor die package (block 840). For example, one or more semiconductor processing tools may be used to bond a fourth active IC die (e.g., an active IC die 606) to a second side of the first active IC die opposing the first side such that the first active IC die and the fourth active IC die are stacked and vertically arranged in a semiconductor die package (e.g., a semiconductor die package 602), as described herein.

As further shown in FIG. 8, process 800 may include providing a first non-active die on a second side of the second active IC die opposing the first side such that the second active IC die and the first non-active die are stacked and vertically arranged in the semiconductor die package (block 850). For example, one or more semiconductor processing tools may be used to provide a first non-active die (e.g., a non-active die 608a) to a second side of the second active IC die opposing the first side such that the second active IC die and the first non-active die are stacked and vertically arranged in the semiconductor die package, as described herein. In some implementations, the first non-active die is laterally adjacent to the fourth active IC die and is spaced apart from the fourth active IC die.

As further shown in FIG. 8, process 800 may include providing a second non-active die on the second side of the third active IC die such that the third active IC die and the second non-active die are stacked and vertically arranged in the semiconductor die package (block 860). For example, one or more semiconductor processing tools may be used to provide a second non-active die (e.g., a non-active die 608b) on the second side of the third active IC die such that the third active IC die and the second non-active die are stacked and vertically arranged in the semiconductor die package, as described herein. In some implementations, the second non-active die is laterally adjacent to the fourth active IC die and is spaced apart from the fourth non-active die.

Process 800 may include additional implementations, such as any single implementation or any combination of implementations described below and/or in connection with one or more other processes described elsewhere herein.

In a first implementation, a portion of the second non-active die is also located on and vertically arranged with the second active IC die.

In a second implementation, alone or in combination with the first implantation, process 800 includes providing a third non-active die (e.g., a non-active die 608c) on and vertically arranged with the third active IC die, where the third non-active die is laterally adjacent to the second non-active die.

In a third implementation, alone or in combination with one of more of the first or second implementations, the first non-active die, the second non-active die, and the third non-active die each include a different material composition.

In a fourth implementation, alone or in combination with one of more of the first through third implementations, a top view area of the second non-active die and a top view area of the third non-active die are approximately a same top view area, and a top view area of the first non-active die is different from the top view area of the second non-active die and the top view area of the third non-active die.

In a fifth implementation, alone or in combination with one or more of the first through fourth implementations, the second active IC die includes a logic die, the third active IC die includes a silicon photonics die, the first non-active die includes a semiconductor non-active die, and the second non-active die includes a dielectric film.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

In this way, a physically smaller first IC die is directly bonded together with a physically lager second IC die in a vertical arrangement in a semiconductor die package. The smaller physical size of the first IC die enables a plurality of non-active dies to be placed over the second IC die in areas not occupied by the first IC die. Including a plurality of non-active dies enables the non-active dies to be customized for the different attributes of different areas of the second IC die. For example, different non-active dies may be manufactured to have different heat dissipation profiles for different areas of the second IC die that have different thermal requirements. As another example, different non-active dies may be manufactured to have different materials to account for areas of different rates of thermal expansion and contraction in the second IC die. In this way, including a plurality of non-active dies in the semiconductor die package may increase the thermal stability of the semiconductor die package, which may enable increased operational lifetime to be achieved for the IC dies, may reduce the likelihood of failure of the IC dies, and/or may increase the overall reliability of the semiconductor die package, among other examples.

As described in greater detail above, some implementations described herein provide a semiconductor die package. The semiconductor die package includes a first active IC die. The semiconductor die package includes a second active IC die over a first portion of the first active IC die. The semiconductor die package includes a first non-active die over a second portion of the first active IC die. The semiconductor die package includes a second non-active die over a third portion of the first active IC die, where the second active IC die, the first non-active die, and the second non-active die are located over a same side of the first IC die.

As described in greater detail above, some implementations described herein provide a method. The method includes attaching a first side of a first active integrated circuit (IC) die to a carrier substrate. The method includes bonding a second active IC die to a second side of the first active IC die opposing the first side such that the first active IC die and the second active IC die are stacked and vertically arranged in a semiconductor die package, providing a first non-active die over the second side of the first active IC die such that the first non-active die is spaced apart from, and laterally adjacent to, the second active IC die. The method includes providing a second non-active die over the second side of the first active IC die such that the second non-active die is laterally adjacent to the first non-active die and such that the second non-active die is spaced apart from, and laterally adjacent to, the second active IC die. The method includes forming a dielectric fill layer around the second active IC die, the first non-active die, and the second non-active die.

As described in greater detail above, some implementations described herein provide a semiconductor die package. The semiconductor die package includes a first active IC die. The semiconductor die package includes a second active IC die laterally adjacent to the first active IC die. The semiconductor die package includes a third active IC die laterally adjacent to the first active IC die and laterally adjacent to the second active IC die. The semiconductor die package includes a fourth active IC die over and vertically arranged with the first active IC die. The semiconductor die package includes a first non-active die over and vertically arranged with the second active IC die. The semiconductor die package includes a second non-active die over and vertically arranged with the third active IC die.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor die package, comprising:
a first active integrated circuit (IC) die;
a second active IC die over a first portion of the first active IC die;
a first non-active die over a second portion of the first active IC die; and
a second non-active die over a third portion of the first active IC die,
wherein the second active IC die, the first non-active die, and the second non-active die are located over a same side of the first IC die.

2. The semiconductor die package of claim 1, wherein the first non-active die and the second non-active die are spaced apart by a gap; and
wherein the semiconductor die package further comprises a dielectric fill layer surrounding the second active IC die, the first non-active die, and the second non-active die,
wherein the dielectric fill layer is included in the gap between the first non-active die and the second non-active die.

3. The semiconductor die package of claim 1, wherein the first non-active die and the second non-active die are in contact along a first side of the first non-active die and a second side of the second non-active die.

4. The semiconductor die package of claim 3, wherein a third side of the second active IC die is adjacent to a fourth side of the first non-active die; and
wherein the third side of the second active IC die is adjacent to a fifth side of the second non-active die.

5. The semiconductor die package of claim 1, wherein the first non-active die comprises a semiconductor non-active die having a semiconductor structure; and
wherein the second non-active die comprises a dielectric non-active die having a dielectric structure.

6. The semiconductor die package of claim 1, wherein the first non-active die is adjacent to a first side of the second active IC die; and
wherein the second non-active die is adjacent to a second side of the second active IC die opposing the first side.

7. The semiconductor die package of claim 1, further comprising a third non-active die over a fourth portion of the first active IC die,
wherein the first non-active die, the second non-active die, and the third non-active die are different sizes.

8. A method, comprising:
attaching a first side of a first active integrated circuit (IC) die to a substrate;
bonding a second active IC die to a second side of the first active IC die opposing the first side such that the first active IC die and the second active IC die are stacked and vertically arranged in a semiconductor die package;
providing a first non-active die on the second side of the first active IC die such that the first non-active die is spaced apart from, and laterally adjacent to, the second active IC die;
providing a second non-active die on the second side of the first active IC die such that the second non-active die is laterally adjacent to the first non-active die and such that the second non-active die is spaced apart from, and laterally adjacent to, the second active IC die; and
forming a dielectric fill layer around the second active IC die, the first non-active die, and the second non-active die.

9. The method of claim 8, wherein providing the first non-active die on the second side of the first active IC die comprises:
placing the non-active die on the second side of the first active IC die.

10. The method of claim 9, wherein providing the second non-active die on the second side of the first active IC die comprises:
depositing the non-active die as a film on the second side of the first active IC die.

11. The method of claim 8, wherein providing the first non-active die on the second side of the first active IC die comprises:
bonding a conductive trench structure in the first non-active die to a bonding pad in the first active IC die.

12. The method of claim 11, wherein the conductive trench structure comprises a plurality of interconnected conductive trenches arranged in a grid.

13. The method of claim 8, wherein providing the first non-active die on the second side of the first active IC die comprises:
bonding a conductive via structure in the first non-active die with a bonding pad in the first active IC die.

14. The method of claim 13, further comprising: forming the conductive via structure in at least one of a semiconductor layer or a dielectric layer of the first non-active die; and
forming a conductive trench structure such that the conductive trench structure is coupled to the conductive via structure.

15. A package, comprising:
a first integrated circuit (IC) die;
a second IC die laterally adjacent to the first IC die;
a third IC die laterally adjacent to the first active IC die and laterally adjacent to the second active IC die;
a fourth IC die over and vertically arranged with the first IC die;
a first non-active die over and vertically arranged with the second IC die; and
a second non-active die over and vertically arranged with the third IC die.

16. The semiconductor die package of claim 15, wherein a portion of the second non-active die is also located over and vertically arranged with the second active IC die.

17. The semiconductor die package of claim 15, further comprising a third non-active die over and vertically arranged with the third active IC die,
wherein the third non-active die is laterally adjacent to the second non-active die.

18. The semiconductor die package of claim 17, wherein the first non-active die, the second non-active die, and the third non-active die comprise different material compositions.

19. The semiconductor die package of claim 17, wherein a top view area of the second non-active die and a top view area of the third non-active die have approximately a same top view area; and
wherein a top view area of the first non-active die is different from the top view area of the second non-active die and the top view area of the third non-active die.

20. The semiconductor die package of claim 15, wherein the second active IC die comprises a logic die;
wherein the third active IC die comprises a silicon photonics die;
wherein the first non-active die comprises a semiconductor non-active die; and
wherein the second non-active die comprises a dielectric film.
